(19) United States
(12) Patent Application Publication
(10) Pub. No.: US 2026/0026233 A1
(43) Pub. Date: Jan. 22, 2026

(54) ELECTRONIC DEVICE MANUFACTURING METHOD

(71) Applicant: Samsung Display Co., LTD., Yongin-si (KR)

(72) Inventors: MOONJUNG BAEK, Yongin-si (KR); SOONKYEONG KWON, Yongin-si (KR); YOUNGMIN KIM, Yongin-si (KR); HYUNWOO NOH, Yongin-si (KR); HAEIL PARK, Yongin-si (KR); HYUN-SUK PARK, Yongin-si (KR); DAEHO LEE, Yongin-si (KR); SUJI HAN, Yongin-si (KR)

(21) Appl. No.: 19/096,256

(22) Filed: Mar. 31, 2025

(30) Foreign Application Priority Data
Jul. 17, 2024 (KR) 10-2024-0094703
Dec. 13, 2024 (KR) 10-2024-0185458

(51) Int. Cl. H10K 59/80; H10K 59/12

(52) U.S. Cl. CPC H10K 59/80518; H10K 59/1201

(57) ABSTRACT

Disclosed is an electronic device manufacturing method which includes forming a base layer, forming a circuit element layer, and forming a display element layer. The forming the display element layer includes forming a first anode in each of a first emissive area, a second emissive area, and a third emissive area, forming a first etching stopper layer on the first anode, forming a first insulating layer on the first etching stopper layer, forming a second etching stopper layer, forming a second insulating layer, etching the first insulating layer and the second insulating layer, etching the first etching stopper layer and the second etching stopper layer, and forming a second anode over the first anode.

### CROSS-REFERENCE TO RELATED APPLICATIONS

The present application claims priority to and the benefits of Korean Patent Application No. 10-2024-0094703, filed on Jul. 17, 2024, in the Korean Intellectual Property Office, and Korean Patent Application No. 10-2024-0185458, filed on Dec. 13, 2024, in the Korean Intellectual Property Office, the entire content of which is hereby incorporated by reference.

### BACKGROUND

Embodiments of the present disclosure described herein relate to an electronic device manufacturing method that provides improved display quality.

In general, electronic devices, such as a smart phone, a digital camera, a notebook computer, a car navigation device, a smart television, and the like, which provide an image to a user include an electronic device to display an image. The electronic device generates an image and provides the generated image to the user through a display screen.

The electronic device includes a display panel including a plurality of pixels to generate an image, a scan driver that applies scan signals to the pixels, and a data driver that applies data voltages to the pixels. The pixels receive the data voltages in response to the scan signals and generate an image using the data voltages.

High-resolution electronic devices are in demand these days. The display panel includes a display area and a non-display area around the display area, and the pixels are provided in the display area. As the number of pixels provided in the display area increases, the resolution of the electronic device increases. In order to increase the number of pixels provided in the display area, development of technology for reducing the size of the pixels is desired or required.

### SUMMARY

Embodiments of the present disclosure provide an electronic device manufacturing method that provides improved display quality.

According to an embodiment, an electronic device manufacturing method includes forming a base layer, forming a circuit element layer on the base layer, and forming a display element layer on the circuit element layer. The display element layer includes forming a first anode in each of a first emissive area, a second emissive area, and a third emissive area, forming a first etching stopper layer on the first anode, forming a first insulating layer (e.g., a first electrically insulating layer) on the first etching stopper layer, forming a second etching stopper layer, forming a second insulating layer (e.g., a second electrically insulating layer), etching the first insulating layer and the second insulating layer, etching the first etching stopper layer and the second etching stopper layer, and forming a second anode over the first anode.

The forming the display element layer may further include forming a third insulating layer (e.g., a third electrically insulating layer) between the first anode and the first etching stopper layer, and the forming the third insulating layer may be performed between the forming the first anode and the forming the first etching stopper layer.

The first anode may include a reflective metal layer.

The second anode may include a transparent electrode.

The forming the first etching stopper layer may include forming the first etching stopper layer such that the first etching stopper layer overlaps the first emissive area when viewed from above a plane (e.g., in a plan view).

The forming the second etching stopper layer may include forming the second etching stopper layer such that the second etching stopper layer overlaps the second emissive area when viewed from above the plane (e.g., in a plan view).

The etching the first insulating layer and the second insulating layer may include exposing the circuit element layer in an area that does not overlap the first emissive area, the second emissive area, and the third emissive area.

A first thickness between the first anode and the second anode in the first emissive area may be less than a second thickness between the first anode and the second anode in the second emissive area.

The second thickness may be less than a third thickness between the first anode and the second anode in the third emissive area.

The forming the second anode may include thermally curing the second anode.

The forming the second anode may further include removing outgas in the circuit element layer.

The first anode and the second anode may overlap each other when viewed from above a plane (e.g., in a plan view).

The first anode may make contact with the second anode in the first emissive area.

The forming the display element layer may further include forming a contact hole that overlaps the first anode when viewed from above a plane (e.g., in a plan view), and the forming the contact hole may be performed between the etching the first etching stopper layer and the second etching stopper layer and the forming the second anode.

A first contact hole that exposes a portion of the first anode may be defined in the first etching stopper layer, and a second contact hole that exposes a portion of the first anode may be defined in the second etching stopper layer.

The forming the display element layer may further include forming photoresist on the second insulating layer that overlaps the third emissive area, and the forming the photoresist may be performed between the forming the second insulating layer and the etching the first insulating layer and the second insulating layer.

According to an embodiment, an electronic device manufacturing method includes forming a base layer, forming a circuit element layer on the base layer, and forming a display element layer on the circuit element layer. The forming the display element layer includes forming a first anode in each of a first emissive area, a second emissive area, and a third emissive area, forming a first insulating layer (e.g., a first electrically insulating layer), forming a second insulating layer (e.g., a second electrically insulating layer) on the first insulating layer, forming a third insulating layer (e.g., a third electrically insulating layer) on the second insulating layer, etching the first insulating layer, the second insulating layer, and the third insulating layer, and forming a second anode on the first anode. A first thickness between the first anode and the second anode in the first emissive area is less than a second thickness between the first anode and the second anode in the second emissive area, and the second thickness is less than a third thickness between the first anode and the second anode in the third emissive area.

The first anode may include a reflective metal layer.

The second anode may include a transparent electrode.

The first anode and the second anode may overlap each other when viewed from above a plane (e.g., in a plan view).

### BRIEF DESCRIPTION OF THE DRAWINGS

The above and other objects and features of embodiments the present disclosure will become apparent by describing in more detail embodiments thereof with reference to the accompanying drawings.

FIG. 1 is a block diagram illustrating an electronic device according to an embodiment of the present disclosure.

FIG. 2 is a perspective view of the electronic device according to an embodiment of the present disclosure.

FIG. 3 is a cross-sectional view of the electronic device according to an embodiment of the present disclosure.

FIG. 4 is a cross-sectional view illustrating a display panel according to an embodiment of the present disclosure.

FIG. 5 is a plan view of the display panel according to an embodiment of the present disclosure.

FIG. 6 is a perspective view illustrating an electronic device according to an embodiment of the present disclosure.

FIG. 7 is an exploded perspective view of the electronic device according to an embodiment of the present disclosure.

FIG. 8 is an enlarged plan view illustrating a portion of a display area of the display panel according to an embodiment of the present disclosure.

FIG. 9 is a cross-sectional view of the display panel taken along line I-I′ of FIG. 8 according to an embodiment of the present disclosure.

FIG. 10 is a cross-sectional view of the electronic device taken along line II-II′ of FIG. 8 according to an embodiment of the present disclosure.

FIG. 11 is a cross-sectional view illustrating a comparison of first to third light emitting elements according to an embodiment of the present disclosure.

FIGS. 12 and 13 are flowcharts illustrating an electronic device manufacturing method according to an embodiment of the present disclosure.

FIG. 14A is a cross-sectional view illustrating forming a first insulating layer according to an embodiment of the present disclosure.

FIG. 14B is a cross-sectional view illustrating forming a first etching stopper layer according to an embodiment of the present disclosure.

FIG. 14C is a cross-sectional view illustrating forming a second insulating layer according to an embodiment of the present disclosure.

FIG. 14D is a cross-sectional view illustrating forming a second etching stopper layer according to an embodiment of the present disclosure.

FIG. 14E is a cross-sectional view illustrating forming a third insulating layer according to an embodiment of the present disclosure.

FIG. 14F is a cross-sectional view illustrating etching the insulating layers according to an embodiment of the present disclosure.

FIG. 14G is a cross-sectional view illustrating etching the etching stopper layers according to an embodiment of the present disclosure.

FIG. 14H is a cross-sectional view illustrating forming a contact hole according to an embodiment of the present disclosure.

FIG. 14I is a cross-sectional view illustrating forming a second anode according to an embodiment of the present disclosure.

FIGS. 14J and 14K are cross-sectional views illustrating the electronic device manufacturing method according to an embodiment of the present disclosure.

FIG. 15 is a flowchart illustrating an electronic device manufacturing method according to an embodiment of the present disclosure.

FIG. 16A is a cross-sectional view illustrating forming a first etching stopper layer according to an embodiment of the present disclosure.

FIG. 16B is a cross-sectional view illustrating forming a first insulating layer according to an embodiment of the present disclosure.

FIG. 16C is a cross-sectional view illustrating forming a second anode according to an embodiment of the present disclosure.

FIG. 17A is a cross-sectional view illustrating an electronic device manufacturing method according to an embodiment of the present disclosure.

FIGS. 17B and 17C are cross-sectional views illustrating the electronic device manufacturing method according to an embodiment of the present disclosure.

FIG. 17D is a cross-sectional view illustrating the electronic device manufacturing method according to an embodiment of the present disclosure.

FIG. 17E is a cross-sectional view illustrating the electronic device manufacturing method according to an embodiment of the present disclosure.

### DETAILED DESCRIPTION

In this specification, when a component (or, an area, a layer, a part, and/or the like) is referred to as being “on”, “connected to” or “coupled to” another component, this means that the component may be directly on, connected to, or coupled to the other component or a third component may be present therebetween.

Identical reference numerals refer to identical components. In the drawings, the thicknesses, proportions, and dimensions of components may be exaggerated for effective description. As used herein, the term “and/or” includes all of one or more combinations defined by related components.

Terms such as first, second, and the like may be used to describe various components, but the components should not be limited by the terms. The terms may be used only to distinguish one component from other components. For example, without departing the scope of the present disclosure, a first component may be referred to as a second component, and similarly, the second component may also be referred to as the first component. The terms of a singular form may include plural forms unless otherwise specified.

In embodiments, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

The terms “part” and “unit” mean a software component or a hardware component that performs a set or specific function. The hardware component may include, for example, a field-programmable gate array (FPGA) or an application-specific integrated circuit (ASIC). The software component may refer to executable code and/or data used by executable code in an addressable storage medium. Thus, software components may be, for example, object-oriented software components, class components, and working components, and may include processes, functions, properties, procedures, subroutines, program code segments, drivers, firmware, micro-codes, circuits, data, databases, data structures, tables, arrays and/or variables.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

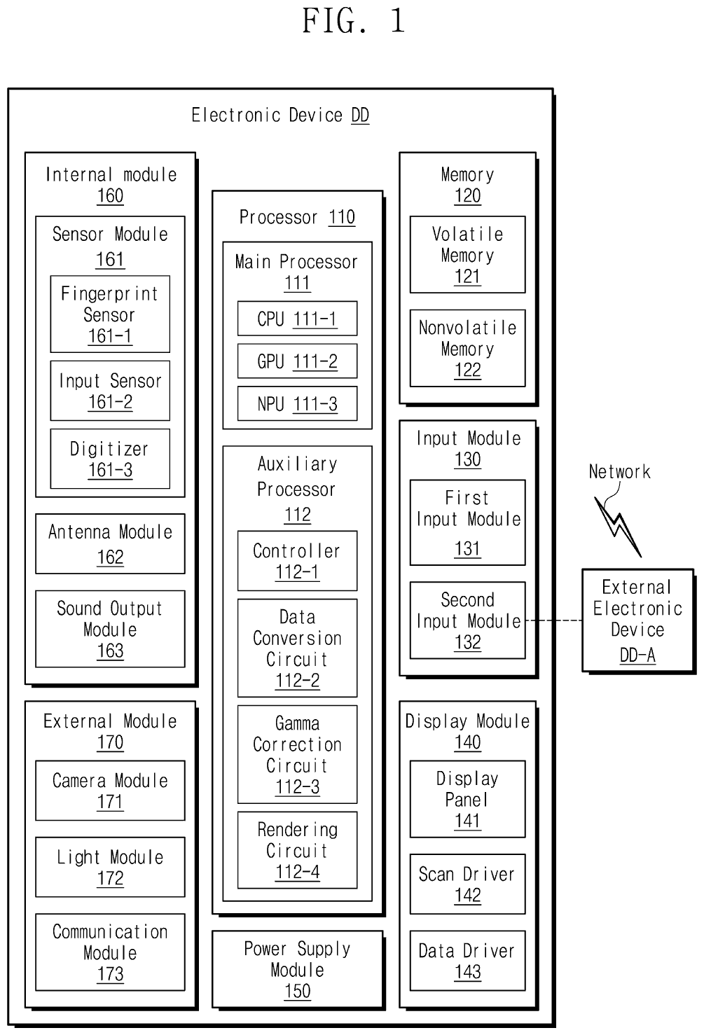

FIG. 1 is a block diagram illustrating an electronic device according to an embodiment of the present disclosure.

Referring to FIG. 1, the electronic device DD outputs various suitable pieces of information through a display module 140 in an operating system. When a processor 110 executes an application stored in a memory 120, the display module 140 provides application information to a user through a display panel 141.

The processor 110 obtains an external input through an input module 130 or a sensor module 161 and executes an application corresponding to the external input. For example, when the user selects a camera icon displayed on the display panel 141, the processor 110 obtains the user input through an input sensor 161-2 and activates a camera module 171. The processor 110 transfers image data corresponding to a photographed image obtained through the camera module 171 to the display module 140. The display module 140 may display an image corresponding to the photographed image through the display panel 141.

In another example, when authentication for personal information is performed on the display module 140, a fingerprint sensor 161-1 obtains input fingerprint information as input data. The processor 110 compares the input data obtained through the fingerprint sensor 161-1 with authentication data stored in the memory 120 and executes an application depending on a comparison result. The display module 140 may display, through the display panel 141, information executed depending on logic of the application.

In another example, when the user selects a music streaming icon displayed on the display module 140, the processor 110 obtains the user input through the input sensor 161-2 and activates a music streaming application stored in the memory 120. When a music play command is input to the music streaming application, the processor 110 activates a sound output module 163 and provides sound information corresponding to the music play command to the user.

The operation of the electronic device DD has been briefly described above. Hereinafter, a configuration of the electronic device DD will be described in more detail. Some of the components of the electronic device DD to be described below may be integrally implemented with one component, and the one component may be divided into two or more components.

The electronic device DD may communicate with an external electronic device DD-A over a network (e.g., a short-range wireless communication network or a long-range wireless communication network). According to an embodiment, the electronic device DD may include the processor 110, the memory 120, the input module 130, the display module 140, a power supply module 150, an internal module 160, and an external module 170. According to an embodiment, the electronic device DD may not include at least one of the above-described components and/or may further include one or more other components. According to an embodiment, some of the above-described components (e.g., the sensor module 161, an antenna module 162, and/or the sound output module 163) may be integrated into any other suitable component (e.g., the display module 140).

The processor 110 may execute software to control at least one other component (e.g., a hardware and/or software component) of the electronic device DD connected to the processor 110 and may perform various suitable data processing and/or operations. According to an embodiment, as at least a part of the data processing and/or operations, the processor 110 may store a command and/or data received from any other suitable component (e.g., the input module 130, the sensor module 161, and/or a communication module 173) in a volatile memory 121, may process the command and/or data stored in the volatile memory 121, and may store the processed data in a nonvolatile memory 122.

The processor 110 may include a main processor 111 and an auxiliary processor 112. The main processor 111 may include at least one selected from a central processing unit (CPU) 111-1 and an application processor (AP). The main processor 111 may further include at least one selected from a graphic processing unit (GPU) 111-2, a communication processor (CP), and an image signal processor (ISP). The main processor 111 may further include a neural processing unit (NPU) 111-3. The neural processing unit 111-3 may be a processor specialized to process an artificial intelligence model, and the artificial intelligence model may be created through machine learning. The artificial intelligence model may include a plurality of artificial neural network layers. The artificial neural network may include a deep neural network (DNN), a convolutional neural network (CNN), a recurrent neural network (RNN), a restricted boltzmann machine (RBM), a deep belief network (DBN), a bidirectional recurrent deep neural network (BRDNN), a deep Q-network, or combinations of two or more thereof, but the present disclosure is not limited thereto. Additionally or alternatively, the artificial intelligence model may include a software structure in addition to a hardware structure. At least two of the above-described processing units and processors may be integrally implemented with one component (e.g., a single chip), or each of the above-described processing units and processors may be implemented with an independent component (e.g., a plurality of chips).

The auxiliary processor 112 may include a controller 112-1. The controller 112-1 may include an interface conversion circuit and a timing control circuit. The controller 112-1 receives an image signal from the main processor 111 and outputs image data obtained by converting the data format of the image signal according to the specification of an interface with the display module 140. The controller 112-1 may output various suitable types (or kinds) of control signals utilized or required to drive the display module 140.

The auxiliary processor 112 may further include a data conversion circuit 112-2, a gamma correction circuit 112-3, and a rendering circuit 112-4. The data conversion circuit 112-2 may receive image data from the controller 112-1. The data conversion circuit 112-2 may compensate for the image data such that an image is displayed to have a suitable or desired luminance depending on a characteristic of the electronic device DD and/or user settings and/or may convert the image data to reduce power consumption and/or to compensate for afterimages. The gamma correction circuit 112-3 may convert the image data and/or the gamma reference voltage such that an image displayed on the electronic device DD has a suitable or desired gamma characteristic. The rendering circuit 112-4 may receive the image data from the controller 112-1 and may make the image data subject to rendering in consideration of a pixel arrangement of the display panel 141 applied to the electronic device DD. At least one selected from the data conversion circuit 112-2, the gamma correction circuit 112-3, and the rendering circuit 112-4 may be integrated into any other suitable component (e.g., the main processor 111 and/or the controller 112-1). At least one selected from the data conversion circuit 112-2, the gamma correction circuit 112-3, and the rendering circuit 112-4 may be integrated into a data driver 143 to be described below.

The memory 120 may store various suitable data used by at least one component (e.g., the processor 110 and/or the sensor module 161) of the electronic device DD and input data and/or output data for commands related thereto. The memory 120 may include at least one selected from the volatile memory 121 and the nonvolatile memory 122.

The input module 130 may receive a command and/or data to be used by a component (e.g., the processor 110, the sensor module 161, and/or the sound output module 163) of the electronic device DD from outside the electronic device DD (e.g., the user and/or the external electronic device DD-A).

The input module 130 may include a first input module 131 to which a command and/or data is input from the user and a second input module 132 to which a command and/or data is input from the external electronic device DD-A. The first input module 131 may include a microphone, a mouse, a keyboard, a key (e.g., a button), and/or a pen (e.g., a passive pen and/or an active pen). The second input module 132 may support a set or specified protocol capable of wiredly and/or wirelessly connecting to the external electronic device DD-A. According to an embodiment, the second input module 132 may include a high definition multimedia interface (HDMI), a universal serial bus (USB) interface, a secure digital (SD) card interface, and/or an audio interface. The second input module 132 may include a connector capable of being physically connected with the external electronic device DD-A, for example, an HDMI connector, a USB connector, an SD card connector, and/or an audio connector (e.g., a headphone connector).

The display module 140 visually provides information to the user. The display module 140 may include the display panel 141, a scan driver 142, and the data driver 143. The display module 140 may further include a window, a chassis, and/or a bracket to protect the display panel 141.

The display panel 141 may include a liquid crystal display panel, an organic light emitting display panel, and/or an inorganic light emitting display panel, and the type (or kind) of the display panel 141 is not particularly limited. The display panel 141 may be of a rigid type (or kind) or may be of a flexible type (or kind) capable of being rolled and/or folded. The display module 140 may further include a supporter that supports the display panel 141, a bracket, and/or a heat radiating member.

The scan driver 142 may be a driver chip and may be mounted on the display panel 141. In embodiments, the scan driver 142 may be integrated into the display panel 141. For example, the scan driver 142 may include an amorphous silicon TFT gate driver circuit (ASG), a low temperature polycrystalline silicon (LTPS) TFT gate driver circuit, and/or an oxide semiconductor TFT gate driver circuit (OSG) embedded in the display panel 141. The scan driver 142 receives a control signal from the controller 112-1 and outputs scan signals to the display panel 141 in response to the control signal.

The display panel 141 may further include an emission driver. The emission driver outputs an emission control signal to the display panel 141 in response to a control signal received from the controller 112-1. The emission driver may be formed separately from the scan driver 142 or may be integrated into the scan driver 142.

The data driver 143 receives a control signal from the controller 112-1, converts image data into analog voltages (e.g., data voltages) in response to the control signal, and outputs the data voltages to the display panel 141.

The data driver 143 may be integrated into another component (e.g., the controller 112-1). The functions of the interface conversion circuit and the timing control circuit of the controller 112-1 described above may be integrated into the data driver 143.

The display module 140 may further include the emission driver and a voltage generation circuit. The voltage generation circuit may output various suitable types (or kinds) of voltages utilized or required to drive the display panel 141.

The power supply module 150 supplies power to the components of the electronic device DD. The power supply module 150 may include a battery that charges a power supply voltage. The battery may include a primary cell that is not rechargeable, a secondary cell that is rechargeable, and/or a fuel cell. The power supply module 150 may include a power management integrated circuit (PMIC). The PMIC supplies power improved or optimized for the modules described above and modules to be described below. The power supply module 150 may include a wireless power transmission/reception member electrically connected with the battery. The wireless power transmission/reception member may include a plurality of antenna radiators in the form of a coil.

The electronic device DD may further include the internal module 160 and the external module 170. The internal module 160 may include the sensor module 161, the antenna module 162, and the sound output module 163. The external module 170 may include the camera module 171, a light module 172, and the communication module 173.

The sensor module 161 may sense an input by the user's body and/or an input by a pen of the first input module 131 and may generate an electrical signal and/or a data value corresponding to the input. The sensor module 161 may include at least one selected from the fingerprint sensor 161-1, the input sensor 161-2, and a digitizer 161-3.

The fingerprint sensor 161-1 may generate a data value corresponding to the user's fingerprint. The fingerprint sensor 161-1 may include one selected from an optical fingerprint sensor and a capacitive fingerprint sensor.

The input sensor 161-2 may generate a data value corresponding to coordinate information of the input by the user's body and/or the input by the pen. The input sensor 161-2 generates a capacitance change due to the input as a data value. The input sensor 161-2 may sense the input by the passive pen and/or may exchange data with the active pen.

The input sensor 161-2 may measure a biometric signal such as blood pressure, moisture, and/or body fat. For example, when the user touches his/her body part to a sensor layer and/or a sensing panel and does not move during a given time period, the input sensor 161-2 may detect the biometric signal based on a change in an electric field caused by the body part and may output the information desired by the user to the display module 140.

The digitizer 161-3 may generate a data value corresponding to the coordinate information of the input by the pen. The digitizer 161-3 generates the amount of electromagnetic change by the input as a data value. The digitizer 161-3 may sense the input by the passive pen and/or may exchange data with the active pen.

At least one selected from the fingerprint sensor 161-1, the input sensor 161-2, and the digitizer 161-3 may be implemented with a sensor layer formed on the display panel 141 through a continuous (e.g., substantially continuous) process. The fingerprint sensor 161-1, the input sensor 161-2, and the digitizer 161-3 may be provided above/on the display panel 141, and one selected from the fingerprint sensor 161-1, the input sensor 161-2, and the digitizer 161-3, for example, the digitizer 161-3 may be provided below/under the display panel 141.

At least two selected from the fingerprint sensor 161-1, the input sensor 161-2, and the digitizer 161-3 may be integrated into one sensing panel through the same process. When the at least two selected from the fingerprint sensor 161-1, the input sensor 161-2, and the digitizer 161-3 are integrated into the one sensing panel, the sensing panel may be between the display panel 141 and the window provided above/on the display panel 141. According to an embodiment, the sensing panel may be on the window, and the location of the sensing panel is not specifically limited.

At least one selected from the fingerprint sensor 161-1, the input sensor 161-2, and the digitizer 161-3 may be embedded in the display panel 141. In embodiments, at least one selected from the fingerprint sensor 161-1, the input sensor 161-2, and the digitizer 161-3 may be concurrently (e.g., simultaneously) formed through a process of forming elements (e.g., a light emitting element and a transistor) included in the display panel 141.

In embodiments, the sensor module 161 may generate an electrical signal and/or a data value corresponding to a state inside the electronic device DD and/or a state external to the electronic device DD. The sensor module 161 may further include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The antenna module 162 may include one or more antennas to transmit and/or receive a signal and/or power to and/or from an external source. According to an embodiment, through an antenna suitable for a communication method, the communication module 173 may transmit a signal to an external electronic device and/or may receive a signal from the external electronic device. An antenna pattern of the antenna module 162 may be integrated with one component (e.g., the display panel 141) of the display module 140 or the input sensor 161-2.

The sound output module 163, which is a device to output a sound signal to the outside of the electronic device DD, may include, for example, a speaker used for general purposes such as playing multimedia and/or playing record and a receiver used exclusively for receiving calls. According to an embodiment, the receiver and the speaker may be integrally or separately implemented. A sound output pattern of the sound output module 163 may be integrated with the display module 140.

The camera module 171 may photograph or record a still image and/or a moving image. According to an embodiment, the camera module 171 may include one or more lenses, an image sensor, and/or an image signal processor. The camera module 171 may further include an infrared camera capable of measuring the presence or absence of the user, the location of the user, and/or the user's gaze.

The light module 172 may provide light. The light module 172 may include a light emitting diode and/or a xenon lamp. The light module 172 may operate in conjunction with the camera module 171 or may operate independently of the camera module 171.

The communication module 173 may establish a wired and/or wireless communication channel between the electronic device DD and the external electronic device DD-A and may support communication execution through the established communication channel. The communication module 173 may include either or both of a wireless communication module, such as a cellular communication module, a short-range wireless communication module, and/or a global navigation satellite system (GNSS) communication module, and a wired communication module, such as a local area network (LAN) communication module and/or a power line communication module. The communication module 173 may communicate with the external electronic device DD-A over a short-range communication network such as Bluetooth, Wi-Fi direct, and/or infrared data association (IrDA) and/or a long-range communication network such as a cellular network, the Internet, and/or a computer network (e.g., a LAN or WAN). Various suitable types (or kinds) of communication modules 173 described above may be implemented with one chip or may be implemented with separate chips, respectively.

The input module 130, the sensor module 161, and the camera module 171 may be used to control the operation of the display module 140 in conjunction with the processor 110.

The processor 110 outputs commands and/or data to the display module 140, the sound output module 163, the camera module 171, and/or the light module 172 based on input data received from the input module 130. For example, the processor 110 may generate the image data corresponding to the input data applied through the mouse and/or the active pen and may output the image data to the display module 140; in embodiments, the processor 110 may generate command data corresponding to the input data and may output the command data to the camera module 171 and/or the light module 172. When input data is not received from the input module 130 during a given time period, the processor 110 may switch an operating mode of the electronic device DD to a low-power mode or a sleep mode such that the power consumption of the electronic device DD is reduced.

The processor 110 outputs commands and/or data to the display module 140, the sound output module 163, the camera module 171, and/or the light module 172 based on the sensing data received from the sensor module 161. For example, the processor 110 may compare authentication data applied by the fingerprint sensor 161-1 with authentication data stored in the memory 120 and may then execute an application depending on a comparison result. The processor 110 may execute a command based on the sensing data sensed by the input sensor 161-2 and/or the digitizer 161-3 and/or may output image data corresponding to the sensing data to the display module 140. When the sensor module 161 includes a temperature sensor, the processor 110 may receive temperature data associated with the measured temperature from the sensor module 161 and may further perform luminance correction on the image data based on the temperature data.

The processor 110 may receive measurement data about the presence or absence of the user, the location of the user, and/or the user's gaze from the camera module 171. The processor 110 may further perform the luminance correction on the image data based on the measurement data. For example, the processor 110 that determines the presence or absence of the user through the input from the camera module 171 may output, to the display module 140, image data whose luminance is corrected through the data conversion circuit 112-2 and/or the gamma correction circuit 112-3.

Some of the above-described components may be connected with each other through a communication scheme between peripheral devices, for example, a bus, a general purpose input/output (GPIO), a serial peripheral interface (SPI), a mobile industry processor interface (MIPI), and/or an ultra path interconnect (UPI) link and may exchange signals (e.g., commands or data) with each other. The processor 110 may communicate with the display module 140 through a given interface. For example, one of the communication methods described above may be used, and the present disclosure is not limited thereto.

The electronic device DD according to various embodiments of the present disclosure may be implemented as various suitable types (or kinds) of devices. The electronic device DD may include, for example, at least one selected from a portable communication device (e.g., a smart phone), a computer device, a portable multimedia device, a portable medical device, a camera, a wearable device, and home appliances. The electronic device DD according to an embodiment of the present disclosure is not limited to the above-described devices.

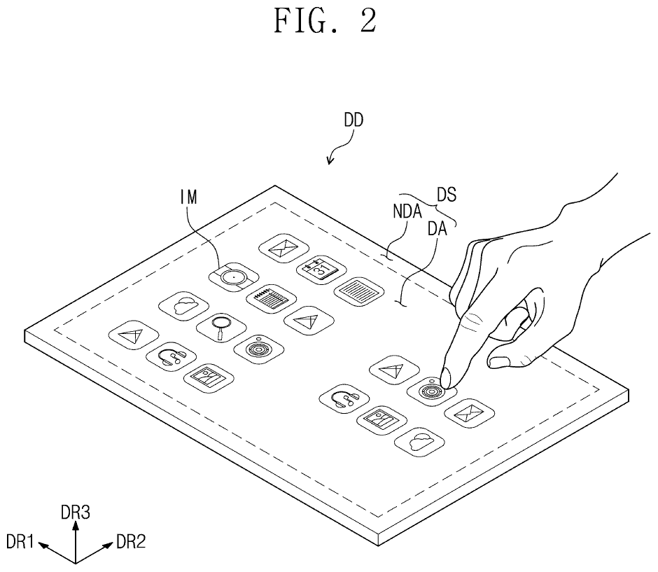

FIG. 2 is a perspective view of the electronic device according to an embodiment of the present disclosure.

Referring to FIG. 2, the electronic device DD according to an embodiment of the present disclosure may have a rectangular shape having long sides that extend in a first direction DR1 and short sides that extend in a second direction DR2 that crosses the first direction DR1. However, without being limited thereto, the electronic device DD may have various suitable shapes such as a circular shape, a polygonal shape, and/or the like.

Hereinafter, a direction substantially perpendicular to a plane defined by the first direction DR1 and the second direction DR2 is defined as a third direction DR3. The expression “when viewed from above the plane” used herein may mean that it is viewed in the third direction DR3.

The upper surface of the electronic device DD may be defined as a display surface DS and may have a plane defined by the first direction DR1 and the second direction DR2. Images IM generated by the electronic device DD may be provided to the user through the display surface DS.

The display surface DS may include a display area DA and a non-display area NDA around the display area DA. The display area DA may display an image, and the non-display area NDA may not display an image. The non-display area NDA may define the border of the electronic device DD that surrounds the display area DA and that is printed in a set or certain color.

The electronic device DD may be used in large electronic devices such as a television, a monitor, and/or a billboard. In embodiments, the electronic device DD may also be used in small and medium-sized electronic devices such as a personal computer, a notebook computer, a personal digital terminal, a car navigation device, a game machine, a smart phone, a tablet computer, and a camera. However, these electronic devices are merely illustrative, and the electronic device DD may be used in other electronic devices without departing from the spirit and scope of the present disclosure.

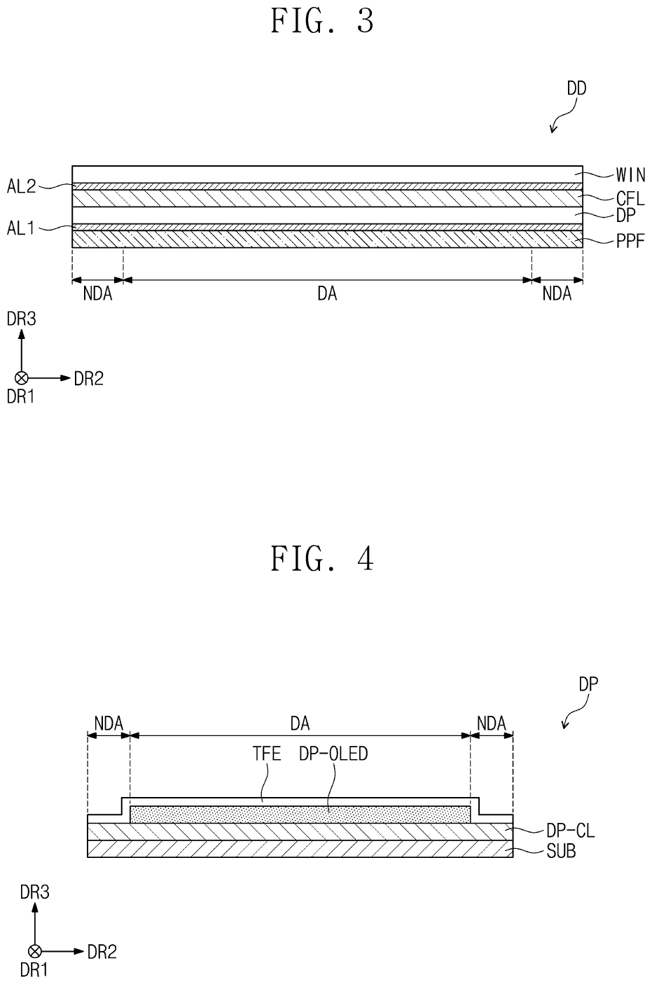

FIG. 3 is a cross-sectional view of the electronic device according to an embodiment of the present disclosure.

Referring to FIG. 3, the electronic device DD may include a display panel DP, a color filter layer CFL, a window WIN, a panel protection film PPF, a first adhesive layer AL1, and a second adhesive layer AL2.

The display panel DP may be a flexible display panel. The display panel DP according to an embodiment of the present disclosure may be an emissive display panel. For example, the display panel DP may be an organic light emitting display panel and/or an inorganic light emitting display panel. An emissive layer of the organic light emitting display panel may include an organic luminescent material. An emissive layer of the inorganic light emitting display panel may include a quantum dot and a quantum rod. Hereinafter, it will be described that the display panel DP is an organic light emitting display panel.

The color filter layer CFL may be on the display panel DP. The color filter layer CFL may decrease the reflectance of external light incident toward the display panel DP from above the electronic device DD. The external light may not be visible to the user due to the color filter layer CFL.

When external light travelling toward the display panel DP is reflected from the display panel DP and provided back to the user, the user may visually recognize the external light as in a mirror. To prevent or reduce such a phenomenon, for example, the color filter layer CFL may include a plurality of color filters that display the same colors as those of pixels of the display panel DP.

The color filters may filter the external light into the same colors as those of the pixels. In embodiments, the external light may not be visible to the user. However, without being limited thereto, the color filter layer CFL may further include a phase retarder and/or a polarizer to decrease the reflectance of the external light.

The window WIN may be on the color filter layer CFL. The window WIN may protect the display panel DP and the color filter layer CFL from external scratches and impacts.

The panel protection film PPF may be under the display panel DP. The panel protection film PPF may protect the bottom of the display panel DP. The panel protection film PPF may include a flexible plastic material such as polyethylene terephthalate (PET).

The first adhesive layer AL1 may be between the display panel DP and the panel protection film PPF, and the display panel DP and the panel protection film PPF may be bonded to each other by the first adhesive layer AL1. The second adhesive layer AL2 may be between the window WIN and the color filter layer CFL, and the window WIN and the color filter layer CFL may be bonded to each other by the second adhesive layer AL2.

FIG. 4 is a cross-sectional view illustrating the display panel according to an embodiment of the present disclosure.

Referring to FIG. 4, the display panel DP may include a base layer SUB, a circuit element layer DP-CL on the base layer SUB, a display element layer DP-OLED on the circuit element layer DP-CL, and a thin film encapsulation layer TFE on the display element layer DP-OLED.

The base layer SUB may include a display area DA and a non-display area NDA around the display area DA. The base layer SUB may include a flexible plastic material such as glass and/or polyimide (PI). The display element layer DP-OLED may be on the display area DA.

A plurality of pixels may be provided in the circuit element layer DP-CL and the display element layer DP-OLED. Each of the pixels may include a transistor provided in the circuit element layer DP-CL and a light emitting element provided in the display element layer DP-OLED and connected to the transistor.

The thin film encapsulation layer TFE may be on the circuit element layer DP-CL to cover the display element layer DP-OLED. The thin film encapsulation layer TFE may protect the pixels from moisture, oxygen, and external foreign matter.

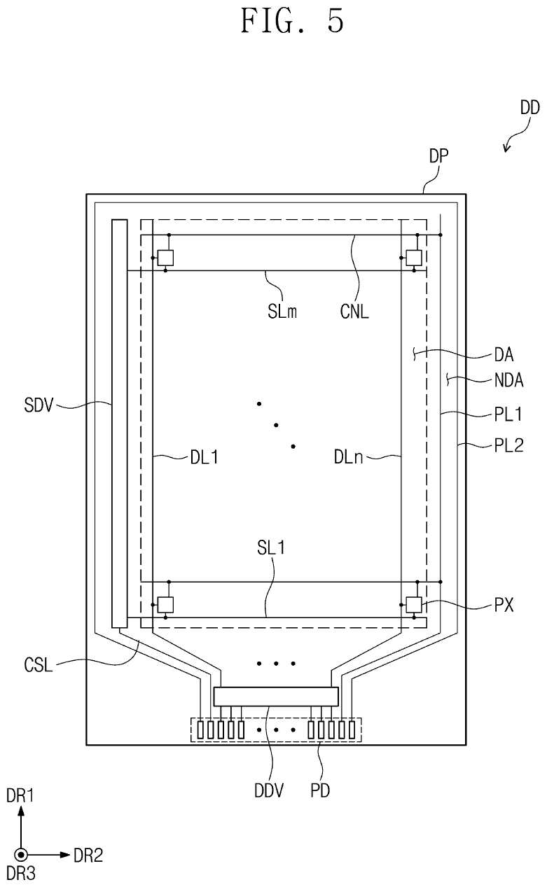

FIG. 5 is a plan view of the display panel according to an embodiment of the present disclosure.

Referring to FIG. 5, the electronic device DD may include the display panel DP, a scan driver SDV, a data driver DDV, and a plurality of pads PD.

The display panel DP may have a rectangular shape having long sides that extend in the first direction DR1 and short sides that extend in the second direction DR2. However, the shape of the display panel DP is not limited thereto. The display panel DP may include a display area DA and a non-display area NDA that surrounds the display area DA.

The display panel DP may include a plurality of pixels PX, a plurality of scan lines SL1 to SLm, a plurality of data lines DL1 to DLn, a control line CSL, a first power line PL1, a second power line PL2, and connecting lines CNL. “m” and “n” are natural numbers.

The pixels PX may be provided in the display area DA. The pixels PX may be provided in a matrix form. However, the arrangement of the pixels PX is not limited thereto.

The scan driver SDV may be provided in the non-display area NDA adjacent to one of the long sides of the display panel DP. The scan driver SDV may be adjacent to the left side of the display panel DP when viewed from above the plane.

The data driver DDV may be provided in the non-display area NDA adjacent to one of the short sides of the display panel DP. The data driver DDV may be adjacent to the lower end of the display panel DP when viewed from above the plane.

The scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV.

The first power line PL1 may extend in the first direction DR1 and may be

provided in the non-display area NDA. The first power line PL1 may be adjacent to the long side of the display panel DP where the scan driver SDV is not provided.

The connecting lines CNL may extend in the second direction DR2 and may be provided in the first direction DR1. The connecting lines CNL may be connected to the first power line PL1 and the pixels PX. A first voltage may be applied to the pixels PX through the first power line PL1 and the connecting lines CNL connected with each other.

The second power line PL2 may be provided in the non-display area NDA and may extend along the long sides of the display panel DP and the other short side of the display panel DP where the data driver DDV is not provided. The second power line PL2 may be provided outward of the scan driver SDV.

In embodiments, the second power line PL2 may extend toward the display area DA and may be connected to the pixels PX. A second voltage may be applied to the pixels PX through the second power line PL2.

The control line CSL may be connected to the scan driver SDV and may extend toward the lower end of the display panel DP. A control signal to control an operation of the scan driver SDV may be provided to the scan driver SDV through the control line CSL.

The pads PD may be provided in the non-display area NDA adjacent to the lower end of the display panel DP and may be closer to the lower end of the display panel DP than the data driver DDV. The data driver DDV, the first power line PL1, the second power line PL2, and the control line CSL may be connected to the pads PD. The data lines DL1 to DLn may be connected to the data driver DDV, and the data driver DDV may be connected to the pads PD corresponding to the data lines DL1 to DLn.

In embodiments, the electronic device DD may further include a timing controller to control operations of the scan driver SDV and the data driver DDV and a voltage generator to generate the first voltage and the second voltage. The timing controller and the voltage generator may be mounted on a printed circuit board and may be connected to the pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn.

The pixels PX may receive the data voltages in response to the scan signals. The pixels PX may display an image by emitting light having luminance corresponding to the data voltages.

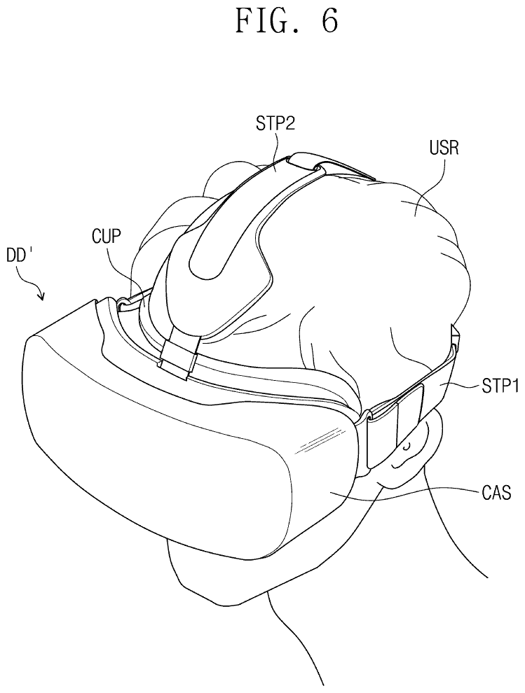

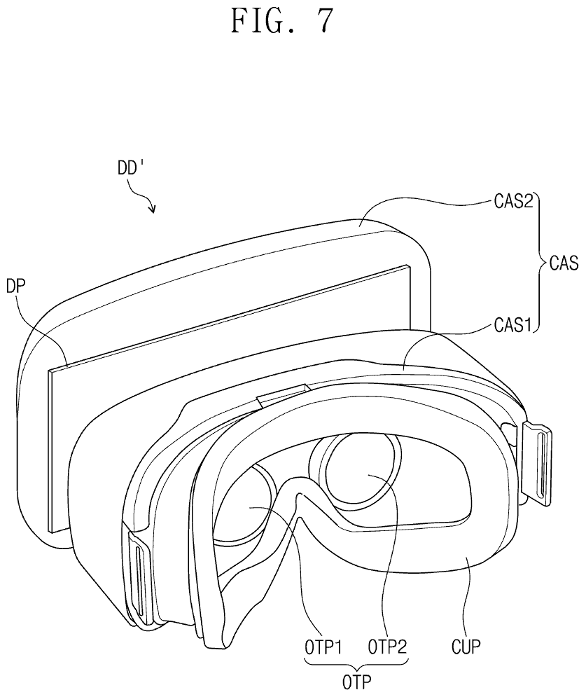

FIG. 6 illustrates an electronic device according to an embodiment of the present disclosure, and FIG. 7 is an exploded perspective view of the electronic device according to an embodiment of the present disclosure.

Referring to FIGS. 6 and 7, the electronic device DD′ may be defined as a head-mounted electronic device. The electronic device DD′ may be worn on the head of a user USR.

The electronic device DD′ may block or reduce a peripheral view of the user USR and may provide an image to the user USR. The electronic device DD′ may provide virtual reality to the user USR.

The electronic device DD′ may include the display panel DP, a casing CAS, a cushion CUP, and straps STP1 and STP2. The casing CAS may be worn on the user USR. The display panel DP that displays an image and an acceleration sensor may be accommodated in the casing CAS.

The acceleration sensor may sense a movement of the user USR and may transfer a set or certain signal to the display panel DP. Accordingly, the display panel DP may provide an image corresponding to a change in the gaze of the user USR. Thus, the user USR may experience virtual reality similar to actual reality.

The cushion CUP may be between the casing CAS and the user USR. The cushion CUP may include a material that is free to deform. For example, the cushion CUP may include a polymer resin (e.g., polyurethane, polycarbonate, polypropylene, and/or polyethylene). In embodiments, the cushion CUP may include a sponge formed by causing liquid rubber, a urethane-based material, and/or an acrylic material to foam.

The cushion CUP may bring the casing CAS into close contact with the user USR to improve the wearing comfort of the user USR. The cushion CUP may be detachable from the casing CAS.

The straps STP1 and STP2 may be coupled with the casing CAS to enable the casing CAS to be easily worn on the user USR. The straps STP1 and STP2 may include the first strap STP1 and the second strap STP2.

The first strap STP1 may be worn along the circumference of the head of the user USR. The first strap STP1 may fix the casing CAS to the user USR to bring the casing CAS into close contact with the head of the user USR.

The second strap STP2 may connect the casing CAS and the first strap STP1 along the upper part of the head of the user USR. The second strap STP2 may prevent the casing CAS from slipping down (or reduce slipping of the casing CAS).

The casing CAS may include a first casing CAS1 and a second casing CAS2. The first casing CAS1 and the second casing CAS2 may be separated from each other.

The display panel DP may be between the first casing CAS1 and the second casing CAS2. The first casing CAS1 and the second casing CAS2 may be coupled with each other, and accordingly the display panel DP may be accommodated in the casing CAS. For example, the display panel DP may provide a left eye image and a right eye image to the user USR. Accordingly, the display panel DP may provide a stereoscopic image to the user USR.

An optical system OTP may be provided in the first casing CAS1. The optical system OTP may magnify an image provided from the display panel DP. The optical system OTP may be between the display panel DP and the eyes of the user USR. The optical system OTP may include a left-eye optical system OTP1 and a right-eye optical system OTP2. The left-eye optical system OTP1 may magnify and provide the image to the left pupil of the user USR, and the right-eye optical system OTP2 may magnify and provide the image to the right pupil of the user USR.

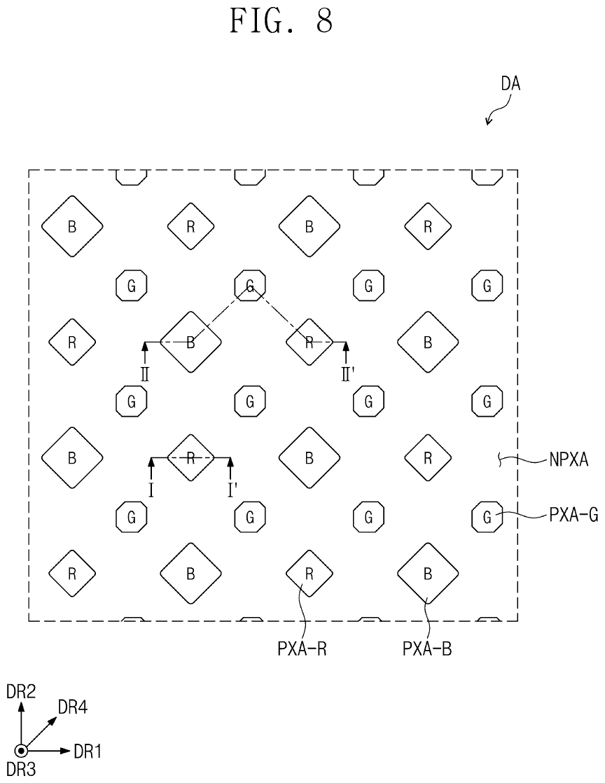

FIG. 8 is an enlarged plan view illustrating a portion of the display area of the display panel according to an embodiment of the present disclosure.

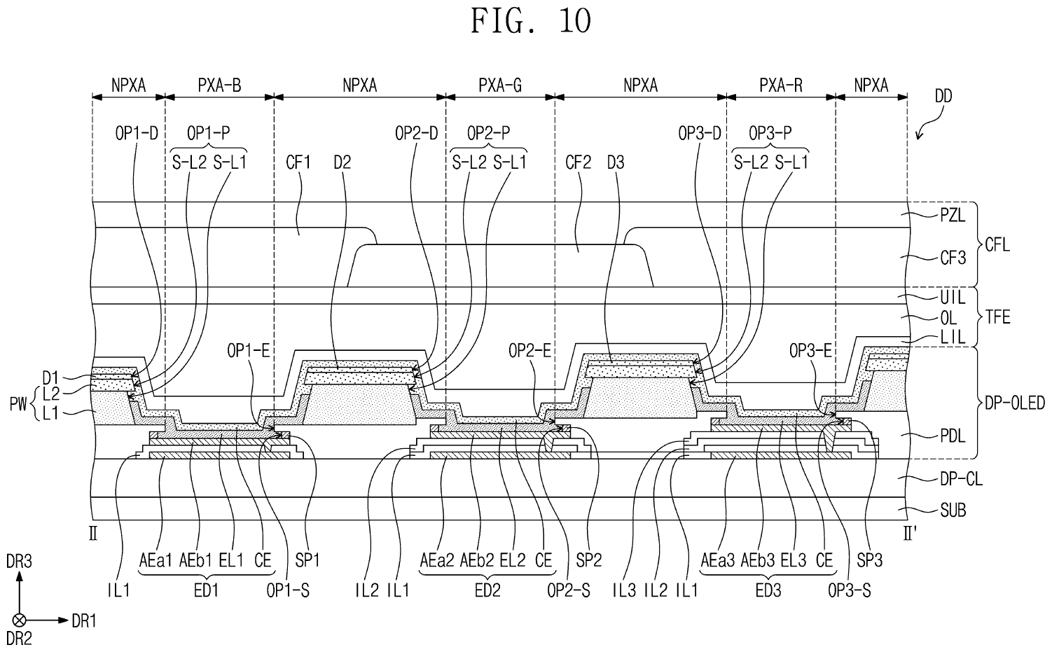

Referring to FIG. 8, the display area DA may include first to third emissive areas PXA-B, PXA-G, and PXA-R and a peripheral area NPXA that surrounds the first to third emissive areas PXA-B, PXA-G, and PXA-R. The first to third emissive areas PXA-B, PXA-G, and PXA-R may correspond to areas through which light provided from light emitting elements ED1, ED2, and ED3 (refer to FIG. 10) is emitted. The first to third emissive areas PXA-B, PXA-G, and PXA-R may be distinguished from one another depending on the colors of light emitted toward the outside of the electronic device DD (refer to FIG. 2).

The first to third emissive areas PXA-B, PXA-G, and PXA-R may provide light of a first color, light of a second color, and light of a third color that have different colors, respectively. For example, the light of the first color may be blue light, the light of the second color may be green light, and the light of the third color may be red light. However, examples of the light of the first color, the light of the second color, and the light of the third color are not necessarily limited thereto.

Each of the first to third emissive areas PXA-B, PXA-G, and PXA-R may be defined as an area where the upper surface of an anode is exposed by a light emitting opening to be further described below. The peripheral area NPXA may set the boundaries between the first to third emissive areas PXA-B, PXA-G, and PXA-R and may prevent or reduce color mixing between the first to third emissive areas PXA-B, PXA-G, and PXA-R.

A plurality of first emissive areas PXA-B, a plurality of second emissive areas PXA-G, and a plurality of third emissive areas PXA-R may be provided. The plurality of first emissive areas PXA-B, the plurality of second emissive areas PXA-G, and the plurality of third emissive areas PXA-R may have a set or certain arrangement in the display area DA and may be repeatedly provided. For example, the first emissive areas PXA-B and the third emissive areas PXA-R may be alternately provided in the first direction DR1 to form a “first group”. The second emissive areas PXA-G may be provided in the first direction DR1 to form a “second group”. A plurality of “first groups” and a plurality of “second groups” may be provided. The “first groups” and the “second groups” may be alternately provided in the second direction DR2.

One second emissive area PXA-G may be spaced apart from one first emissive area PXA-B or one third emissive area PXA-R in a fourth direction DR4. The fourth direction DR4 may be defined as a direction between the first direction DR1 and the second direction DR2.

FIG. 8 illustrates an arrangement of the first to third emissive areas PXA-B, PXA-G, and PXA-R. However, without being limited thereto, the first to third emissive areas PXA-B, PXA-G, and PXA-R may be provided in various suitable forms. In an embodiment, the first to third emissive areas PXA-B, PXA-G, and PXA-R may have a PENTILE® arrangement structure (e.g., an RGBG matrix, RGBG structure, or RGBG matrix structure) as illustrated in FIG. 8. PENTILE® is a duly registered trademark of Samsung Display Co., Ltd. In embodiments, the first to third emissive areas PXA-B, PXA-G, and PXA-R may have a stripe arrangement or a DIAMOND PIXEL™ arrangement. DIAMOND PIXEL™ is a trademark of Samsung Display Co., Ltd.

The first to third emissive areas PXA-B, PXA-G, and PXA-R may have various suitable shapes when viewed from above the plane (e.g., in a plan view). For example, the first to third emissive areas PXA-B, PXA-G, and PXA-R may have a polygonal shape, a circular shape, or an oval shape. FIG. 8 illustrates the first emissive areas PXA-B and the third emissive areas PXA-R having a quadrangular shape (or, a rhombus shape) when viewed from above the plane (e.g., in a plan view) and the second emissive areas PXA-G having an octagonal shape when viewed from above the plane.

The first to third emissive areas PXA-B, PXA-G, and PXA-R may have the same shape when viewed from above the plane (e.g., in a plan view), or at least some of the first to third emissive areas PXA-B, PXA-G, and PXA-R may have different shapes. FIG. 8 illustrates the first emissive areas PXA-B and the third emissive areas PXA-R having the same shape when viewed from above the plane (e.g., in a plan view) and the second emissive areas PXA-G having a shape different from those of the first emissive areas PXA-B and the third emissive areas PXA-R.

At least some of the first to third emissive areas PXA-B, PXA-G, and PXA-R may have different areas when viewed from above the plane (e.g., in a plan view). In an embodiment, the area of the third emissive area PXA-R that emits red light may be greater than the area of the second emissive area PXA-G that emits green light and may be smaller than the area of the first emissive area PXA-B that emits blue light. However, a relative size relationship between the first to third emissive areas PXA-B, PXA-G, and PXA-R depending on the emission colors is not limited thereto and may vary depending on the design of the electronic device DD (refer to FIG. 2). In embodiments, without being limited thereto, the first to third emissive areas PXA-B, PXA-G, and PXA-R may have the same area when viewed from above the plane (e.g., in a plan view).

In embodiments, the shapes, areas, and arrangement of the first to third emissive areas PXA-B, PXA-G, and PXA-R of the display panel DP (refer to FIG. 5) of the present disclosure may be diversely designed depending on the colors of emitted light and/or the size and configuration of the display panel DP (refer to FIG. 5) and are not limited to the embodiment illustrated in FIG. 8.

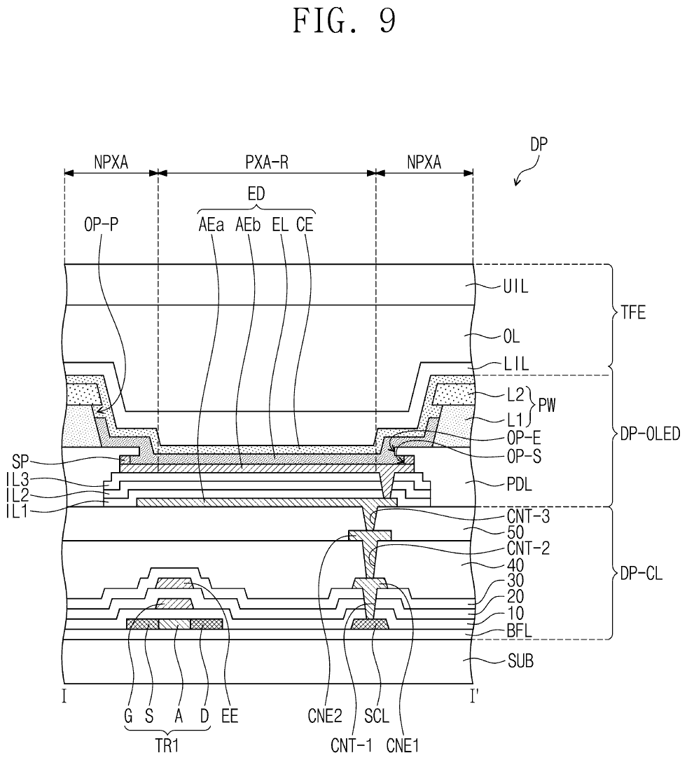

FIG. 9 is a cross-sectional view of the display panel taken along line I-l′ of FIG. 8 according to an embodiment of the present disclosure.

Referring to FIGS. 8 and 9, the display panel DP may include the base layer SUB, the circuit element layer DP-CL, the display element layer DP-OLED, and the thin film encapsulation layer TFE.

The display panel DP may include a plurality of insulating layers (e.g., electrically insulating layers), a semiconductor pattern, a conductive pattern (e.g., an electrically conductive pattern), and a signal line. An insulating layer (e.g., an electrically insulating layer), a semiconductor layer, and a conductive layer (e.g., an electrically conductive layer) are formed by coating, deposition, and/or the like. Thereafter, the insulating layer, the semiconductor layer, and the conductive layer may be selectively subjected to patterning by photolithography and etching. The semiconductor pattern, the conductive pattern, and the signal line included in the circuit element layer DP-CL and the display element layer DP-OLED may be formed by the above-described method.

The circuit element layer DP-CL may be on the base layer SUB. The circuit element layer DP-CL may include a buffer layer BFL, a transistor TR1, a signal transmission area SCL, first to fifth insulating layers (e.g., electrically insulating layers) 10, 20, 30, 40, and 50, an upper electrode EE, and a plurality of connecting electrodes CNE1 and CNE2.

The buffer layer BFL may be on the base layer SUB. The buffer layer BFL may improve the coupling force between the base layer SUB and a semiconductor pattern. The buffer layer BFL may include silicon oxide layers and silicon nitride layers. The silicon oxide layers and the silicon nitride layers may be alternately stacked one above another.

The semiconductor pattern may be on the buffer layer BFL. The semiconductor pattern may include poly silicon. However, without being limited thereto, the semiconductor pattern may include amorphous silicon and/or metal oxide. FIG. 9 merely illustrates the semiconductor pattern corresponding to the third emissive area PXA-R, and the semiconductor pattern may be further provided in the plurality of emissive areas PXA-G and PXA-B. The semiconductor pattern may be provided across the plurality of emissive areas PXA-B, PXA-G, PXA-R according to a set or specific rule. The semiconductor pattern may have different electrical properties depending on whether doping is performed or not. The semiconductor pattern may include first areas having a high doping concentration and a second area having a low doping concentration. The first areas may be doped with an N-type dopant or a P-type dopant. A P-type transistor may include first areas doped with a P-type dopant.

The first areas have a higher conductivity (e.g., electrical conductivity) than the second area and substantially serve as an electrode or a signal line. The second area may substantially correspond to an active (or, channel) area of the transistor. In embodiments, one portion of the semiconductor pattern may be the active area of the transistor, another portion may be the source or drain of the transistor, and the other portion may be a conductive area (e.g., an electrically conductive area).

The source S, the active area A, and the drain D of the transistor TR1 may be formed from the semiconductor pattern. A portion of the signal transmission area SCL formed from the semiconductor pattern is illustrated in FIG. 9. In embodiments, the signal transmission area SCL may be connected to the drain D of the transistor TR1 when viewed from above the plane (e.g., in a plan view).

The first to fifth insulating layers 10, 20, 30, 40, and 50 may be disposed on the buffer layer BFL. The first to fifth insulating layers 10, 20, 30, 40, and 50 may be inorganic layers and/or organic layers.

The first insulating layer 10 may be on the buffer layer BFL. The first insulating layer 10 may cover the source S, the active area A, and the drain D of the transistor TR1 and the signal transmission area SCL that are on the buffer layer BFL. The gate G of the transistor TR1 may be on the first insulating layer 10. The second insulating layer 20 may be on the first insulating layer 10 and may cover the gate G. The upper electrode EE may be on the second insulating layer 20. The third insulating layer 30 may be on the second insulating layer 20 and may cover the upper electrode EE.

The first connecting electrode CNE1 may be on the third insulating layer 30. The first connecting electrode CNE1 may be connected to the signal transmission area SCL through a contact hole CNT-1 that penetrates the first to third insulating layers 10, 20, and 30. The fourth insulating layer 40 may be disposed on the third insulating layer 30 and may cover the first connecting electrode CNE1. The fourth insulating layer 40 may be an organic layer.

The second connecting electrode CNE2 may be on the fourth insulating layer 40. The second connecting electrode CNE2 may be connected to the first connecting electrode CNE1 through a contact hole CNT-2 that penetrates the fourth insulating layer 40. The fifth insulating layer 50 may be on the fourth insulating layer 40 and may cover the second connecting electrode CNE2. The fifth insulating layer 50 may be an organic layer.

The display element layer DP-OLED may be on the circuit element layer DP-CL. The display element layer DP-OLED may include a light emitting element ED, a first insulating layer (e.g., electrically insulating layer) IL1, a second insulating layer (e.g., electrically insulating layer) IL2, a third insulating layer (e.g., electrically insulating layer) IL3, a sacrificial pattern SP, a pixel defining layer PDL, and a partition wall PW.

The light emitting element ED may include a first anode AEa, a second anode AEb, an emissive layer EL, and a cathode CE (or, a second electrode). The light emitting element ED may be provided in a light emitting opening OP-E and a partition wall opening OP-P.

The first anode AEa may be on the fifth insulating layer 50 of the circuit element layer DP-CL. The first anode AEa may include a transmissive electrode, a transflective electrode, or a reflective electrode. The first anode AEa may be connected to the second connecting electrode CNE2 by a connection contact hole CNT-3 defined to penetrate the fifth insulating layer 50. Accordingly, the first anode AEa may be electrically connected to the signal transmission area SCL through the first connecting electrode CNE1 and the second connecting electrode CNE2 and may be electrically connected to a corresponding circuit element.

The first anode AEa may include a single-layer structure or a multi-layer structure. The first anode AEa may include a plurality of layers including indium tin oxide (ITO) and silver (Ag). For example, the first anode AEa may include a layer including ITO (hereinafter, referred to as the lower IOT layer), a layer that is on the lower ITO layer and that includes silver (Ag) (hereinafter, referred to as the Ag layer), and a layer that is on the Ag layer and that includes ITO (hereinafter, referred to as the upper ITO layer).

The first insulating layer IL1 may be on the first anode AEa. The first insulating layer IL1 may cover the first anode AEa.

The second insulating layer IL2 may be on the first insulating layer IL1. The second insulating layer IL2 may cover the first insulating layer IL1.

The third insulating layer IL3 may be on the second insulating layer IL2. The third insulating layer IL3 may cover the second insulating layer IL2.

The first to third insulating layers IL1, IL2, and IL3 may have different stacked structures depending on the plurality of emissive areas PXA-B, PXA-G, and PXA-R. Further description thereof will be given below.

The second anode AEb may be on the third insulating layer IL3. The second anode AEb may include a transmissive electrode. The second anode AEb may be connected to the first anode AEa by a contact hole defined to penetrate the first to third insulating layers IL1, IL2, and IL3. The second anode AEb may include a layer including ITO.

The sacrificial pattern SP may be between the second anode AEb and the pixel defining layer PDL. A sacrificial opening OP-S that exposes a portion of the upper surface of the second anode AEb may be defined in the sacrificial pattern SP. The sacrificial opening OP-S may overlap the light emitting opening OP-E.

The light emitting opening OP-E may correspond to the sacrificial opening OP-S of the sacrificial pattern SP. According to this embodiment, the upper surface of the second anode AEb may be spaced apart from the pixel defining layer PDL on the cross-section with the sacrificial pattern SP therebetween. Accordingly, in a process of forming the light emitting opening OP-E, the second anode AEb may be protected, and damage to the second anode AEb may be prevented, eliminated, or reduced.

When viewed from above the plane (e.g., in a plan view), the area of the light emitting opening OP-E may be smaller than the area of the sacrificial opening OP-S. For example, the inner surface of the pixel defining layer PDL that defines the light emitting opening OP-E may be closer to the center of the second anode AEb than the inner surface of the sacrificial pattern SP that defines the sacrificial opening OP-S. However, this is illustrative, and the inner surface of the sacrificial pattern SP that defines the sacrificial opening OP-S may be substantially the same as the inner surface of the pixel defining layer PDL that defines the light emitting opening OP-E. In embodiments, the third emissive area PXA-R may be an area of the second anode AEb exposed from the corresponding sacrificial opening OP-S.

The pixel defining layer PDL may include an inorganic insulating material (e.g., an inorganic electrically insulating material). For example, the pixel defining layer PDL may include silicon nitride SiNx. The pixel defining layer PDL may be between the second anode AEb and the partition wall PW and may block or reduce electrical connection between the second anode AEb and the partition wall PW.

The emissive layer EL may be on the second anode AEb. The emissive layer EL may include a luminescent material. The emissive layer EL may be subjected to patterning by a tip portion defined in the partition wall PW. The emissive layer EL may be provided in at least one selected from the sacrificial opening OP-S, the light emitting opening OP-E, and the partition wall opening OP-P. However, this is illustrative, and the emissive layer EL may be provided in the sacrificial opening OP-S and the light emitting opening OP-E. The emissive layer EL may cover a portion of the upper surface of the pixel defining layer PDL.

The cathode CE may be on the emissive layer EL. The cathode CE may be on the partition wall PW. The cathode CE may cover the partition wall PW and the emissive layer EL.

The cathode CE may have conductivity (e.g., electrical conductivity). As long as the cathode CE is capable of having conductivity, the cathode CE may be formed of various suitable materials such as metal, transparent conductive oxide (TCO), and/or a conductive polymer material (e.g., an electrically conductive polymer material). For example, the cathode CE may include silver (Ag), magnesium (Mg), lead (Pb), copper (Cu), and/or a compound thereof.

The partition wall PW may be on the pixel defining layer PDL. The partition wall PW including a conductive material (e.g., an electrically conductive material) according to an embodiment of the present disclosure may receive a drive voltage, and accordingly the cathode CE may be electrically connected to the partition wall PW and may receive the drive voltage.

The partition wall PW may include a plurality of layers sequentially stacked one above another. For example, the partition wall PW may include a first partition wall layer L1 and a second partition wall layer L2. The first partition wall layer L1 may be on the pixel defining layer PDL, and the second partition wall layer L2 may be on the first partition wall layer L1. As illustrated in FIG. 9, the thickness of the first partition wall layer L1 may be greater than the thickness of the second partition wall layer L2. However, the present disclosure is not limited thereto.

Each of the first partition wall layer L1 and the second partition wall layer L2 may include a conductive material (e.g., an electrically conductive material). For example, the conductive material may include metal, transparent conductive oxide (TCO), or a combination thereof. For example, the metal may include gold (Au), silver (Ag), aluminum (AI), magnesium (Mg), lithium (Li), molybdenum (Mo), titanium (Ti), copper (Cu), tungsten (W), and/or an alloy. The transparent conductive oxide may include indium tin oxide (ITO), indium zinc oxide (IZO), zinc oxide, indium oxide, indium gallium oxide, indium gallium zinc oxide (IGZO), and/or aluminum zinc oxide. The materials of the first partition wall layer L1 and the second partition wall layer L2 are illustrative and are not limited thereto.

The partition wall PW may have an undercut shape on the cross-section. At least one layer among the plurality of layers of the partition wall PW may be recessed when compared to the other layers, and accordingly the partition wall PW may include the tip portion. For example, the first partition wall layer L1 may have an undercut shape with respect to the second partition wall layer L2. The second partition wall layer L2 may protrude further toward the light emitting opening OP-E than the first partition wall layer L1 to form the tip portion. The portion of the second partition wall layer L2 that protrudes from the first partition wall layer L1 toward the third emissive area PXA-R may be defined as the tip portion in the partition wall PW. For example, the inner surface of the second partition wall layer L2 may be closer to the center of the second anode AEb than the inner surface of the first partition wall layer L1.

The description of the emissive layer EL may be identically applied to the emissive layer EL corresponding to each of the first to third emissive areas PXA-B, PXA-G, and PXA-R.

The thin film encapsulation layer TFE may be on the display element layer DP-OLED. The thin film encapsulation layer TFE may include a lower inorganic encapsulation pattern LIL, an organic encapsulation film OL, and an upper inorganic encapsulation film UIL.

The lower inorganic encapsulation pattern LIL may be on the cathode CE. The lower inorganic encapsulation pattern LIL may cover the cathode CE.

The organic encapsulation film OL may cover the lower inorganic encapsulation pattern LIL and may provide a flat upper surface. The upper inorganic encapsulation film UIL may be on the organic encapsulation film OL.

The lower inorganic encapsulation pattern LIL and the upper inorganic encapsulation film UIL may protect the display element layer DP-OLED from moisture/oxygen, and the organic encapsulation film OL may protect the display element layer DP-OLED from foreign matter such as dust particles.

FIG. 10 is a cross-sectional view of the electronic device taken along line II-II′ of FIG. 8 according to an embodiment of the present disclosure.

In describing FIG. 10, the components described with reference to FIG. 9 will be assigned with similar reference numerals, and redundant description thereof may not be repeated.

Referring to FIGS. 8, 9, and 10, the display panel DP may include a plurality of insulating layers (e.g., electrically insulating layers), a semiconductor pattern, a conductive pattern (e.g., an electrically conductive pattern), a signal line, and/or the like. An insulating layer (e.g., an electrically insulating layer), a semiconductor layer, and a conductive layer (e.g., an electrically conductive layer) are formed by coating, deposition, and/or the like. Thereafter, the insulating layer, the semiconductor layer, and the conductive layer may be selectively subjected to patterning by photolithography and etching. The semiconductor pattern, the conductive pattern, and the signal line included in the circuit element layer DP-CL and the display element layer DP-OLED are formed by the above-described method.

The circuit element layer DP-CL may be on the base layer SUB. Although the circuit element layer DP-CL is illustrated as a single layer, the circuit element layer DP-CL is simply illustrated for ease of description. The circuit element layer DP-CL may include an insulating layer (e.g., an electrically insulating layer), a semiconductor pattern, a conductive pattern (e.g., an electrically conductive pattern), and/or the like for forming various suitable elements.

A plurality of pixel drive circuits may be provided in the circuit element layer DP-CL. The pixel drive circuits may be connected to the light emitting elements ED1, ED2, and ED3, respectively, and may independently control the light emitting elements ED1, ED2, and ED3. Each of the pixel drive circuits may include a plurality of transistors for driving a connected light emitting element, at least one capacitor, and signal lines connecting the transistors and the capacitor.

The display element layer DP-OLED may be on the circuit element layer DP-CL. The display element layer DP-OLED may include the light emitting elements ED1, ED2, and ED3, the pixel defining layer PDL, the partition wall PW, and dummy patterns D1, D2, and D3.

The light emitting elements ED1, ED2, and ED3 may include the first light emitting element ED1, the second light emitting element ED2, and the third light emitting element ED3. Each of the first to third light emitting elements ED1, ED2, and ED3 may include an anode (or, a first electrode), a cathode (or, a second electrode), and an emissive layer between the anode and the cathode.

For example, the first light emitting element ED1 may include a first-first anode AEa1, a second-first anode AEb1, a cathode CE, and a first emissive layer EL1, the second light emitting element ED2 may include a first-second anode AEa2, a second-second anode AEb2, the cathode CE, and a second emissive layer EL2, and the third light emitting element ED3 may include a first-third anode AEa3, a second-third anode AEb3, the cathode CE, and a third emissive layer EL3. The cathode CE may be provided in common to the first light emitting element ED1, the second light emitting element ED2, and the third light emitting element ED3.

A first insulating layer IL1 may be on the first-first anode AEa1. The second-first anode AEb1 may be on the first insulating layer IL1. The first insulating layer IL1 may include silicon oxide (SiOx). The first-first anode AEa1 and the second-first anode AEb1 may be connected with each other through a first contact hole that penetrates the first insulating layer IL1.

The first insulating layer IL1 may be provided in the first emissive area PXA-B.

A first insulating layer IL1 and a second insulating layer IL2 may be on the first-second anode AEa2. The second-second anode AEb2 may be on the second insulating layer IL2. The second insulating layer IL2 may include silicon oxide (SiOx). The first-second anode AEa2 and the second-second anode AEb2 may be connected with each other through a second contact hole that penetrates the first insulating layer IL1 and the second insulating layer IL2.

The first insulating layer IL1 and the second insulating layer IL2 may be provided in the second emissive area PXA-G.

A first insulating layer (e.g., electrically insulating layer) IL1, a second insulating layer (e.g., electrically insulating layer) IL2, and a third insulating layer (e.g., electrically insulating layer) IL3 may be on the first-third anode AEa3. The second-third anode AEb3 may be on the third insulating layer IL3. The third insulating layer IL3 may include silicon oxide (SiOx). The first-third anode AEa3 and the second-third anode AEb3 may be connected with each other through a third contact hole that penetrates the first insulating layer IL1, the second insulating layer IL2, and the third insulating layer IL3.

The first insulating layer IL1, the second insulating layer IL2, and the third insulating layer IL3 may be provided in the third emissive area PXA-R.

The first to third emissive layers EL1, EL2, and EL3 may be on the second anodes AEb1, AEb2, and AEb3, respectively. The first to third emissive layers EL1, EL2, and EL3 may be subjected to patterning by tip portions defined in the partition wall PW to be further described below.

The pixel defining layer PDL may be on the insulating layer provided at the top of the circuit element layer DP-CL. First to third light emitting openings OP1-E, OP2-E, and OP3-E may be defined in the pixel defining layer PDL. The first to third light emitting openings OP1-E, OP2-E, and OP3-E may correspond to the second anodes AEb1, AEb2, and AEb3, respectively. The pixel defining layer PDL may expose at least portions of the second anodes AEb1, AEb2, and AEb3 through the light emitting openings OP1-E, OP2-E, and OP3-E.

The first emissive area PXA-B may be defined as an area of the upper surface of the second-first anode AEb1 that is exposed by the first light emitting opening OP1-E, the second emissive area PXA-G may be defined as an area of the upper surface of the second-second anode AEb2 that is exposed by the second light emitting opening OP2-E, and the third emissive area PXA-R may be defined as an area of the upper surface of the second-third anode AEb3 that is exposed by the third light emitting opening OP3-E.

The pixel defining layer PDL may be an inorganic insulating layer (e.g., an inorganic electrically insulating layer). For example, the pixel defining layer PDL may include silicon oxide, silicon nitride, or a combination thereof. For example, the pixel defining layer PDL may have a two-layer structure in which a silicon oxide layer and a silicon nitride layer are sequentially stacked. However, this is illustrative, and as long as the pixel defining layer PDL is an inorganic insulating layer (e.g., an inorganic electrically insulating layer), the pixel defining layer PDL may be formed of various suitable materials and may have a single-layer structure or a multi-layer structure, and the present disclosure is not limited to any one embodiment.

According to an embodiment of the present disclosure, the display panel DP may further include first to third sacrificial patterns SP1, SP2, and SP3. The first to third sacrificial patterns SP1, SP2, and SP3 may be on the upper surfaces of the second anodes AEb1, AEb2, and AEb3, respectively. The sacrificial patterns SP1, SP2, and SP3 may be covered by the pixel defining layer PDL. The sacrificial patterns SP1, SP2, and SP3 expose at least portions of the corresponding second anodes AEb1, AEb2, and AEb3, respectively. The sacrificial patterns SP1, SP2, and SP3 may be provided in positions not overlapping the light emitting openings OP1-E, OP2-E, and OP3-E, respectively.

When the display panel DP further includes the sacrificial patterns SP1, SP2, and SP3, the upper surfaces of the second anodes AEb1, AEb2, and AEb3 may be spaced apart from the pixel defining layer PDL on the cross-section with the corresponding sacrificial patterns SP1, SP2, and SP3 therebetween. Accordingly, damage to the second anodes AEb1, AEb2, and AEb3 may be prevented or reduced in a process of forming the light emitting openings OP1-E, OP2-E, and OP3-E.

In an embodiment, sacrificial openings OP1-S, OP2-S, and OP3-S corresponding to the light emitting openings OP1-E, OP2-E, and OP3-E may be defined in the sacrificial patterns SP1, SP2, and SP3, respectively. The sacrificial openings OP1-S, OP2-S, and OP3-S may have larger areas than the corresponding light emitting openings OP1-E, OP2-E, and OP3-E. However, without being limited thereto, the inner surfaces of the sacrificial patterns SP1, SP2, and SP3 that define the sacrificial openings OP1-S, OP2-S, and OP3-S may be substantially aligned with the inner surfaces of the pixel defining layer PDL that define the corresponding light emitting openings OP1-E, OP2-E, and OP3-E. In embodiments, the emissive areas PXA-B, PXA-G, and PXA-R may be areas of the second anodes AEb1, AEb2, and AEb3 exposed through the corresponding sacrificial openings OP1-S, OP2-S, and OP3-S.

The partition wall PW may be on the pixel defining layer PDL. First to third partition wall openings OP1-P, OP2-P, and OP3-P may be defined in the partition wall PW.

The first to third partition wall openings OP1-P, OP2-P, and OP3-P may correspond to the first to third light emitting openings OP1-E, OP2-E, and OP3-E, respectively. The partition wall openings OP1-P, OP2-P, and OP3-P may expose at least portions of the corresponding second anodes AEb1, AEb2, and AEb3, respectively.

The partition wall PW may have an undercut shape on the cross-section. Side surfaces S-L1 and S-L2 of the partition wall PW that define the partition wall openings OP1-P, OP2-P, and OP3-P may have an undercut shape on the cross-section. The partition wall PW may include a plurality of layers sequentially stacked one above another, and at least one layer among the plurality of layers may be recessed when compared to layers stacked adjacent thereto. Accordingly, the partition wall PW may include the tip portions.

The emissive layers EL1, EL2, and EL3 may be separated by the tip portions of the partition wall PW and may be formed in the light emitting openings OP1-E, OP2-E, and OP3-E and the partition wall openings OP1-P, OP2-P, and OP3-P.

The partition wall PW may include the first partition wall layer L1 and the second partition wall layer L2 on the first partition wall layer L1. The first partition wall layer L1 may define first areas of the partition wall openings OP1-P, OP2-P, and OP3-P, and the second partition wall layer L2 may define second areas of the partition wall openings OP1-P, OP2-P, and OP3-P. In more detail, the inner surfaces S-L1 of the first partition wall layer L1 may define the first areas of the partition wall openings OP1-P, OP2-P, and OP3-P, and the inner surfaces S-L2 of the second partition wall layer L2 may define the second areas of the partition wall openings OP1-P, OP2-P, and OP3-P.

The first partition wall layer L1 may be on the pixel defining layer PDL. The first partition wall layer L1 may be relatively recessed with respect to the emissive areas PXA-B, PXA-G, and PXA-R when compared to the second partition wall layer L2. On the cross-section, the inner surfaces S-L2 of the second partition wall layer L2 that define the second areas may be closer to the centers of the corresponding second anodes AEb1, AEb2, and AEb3 than the inner surfaces S-L1 of the first partition wall layer L1 that define the first areas. For example, the inner surfaces S-L1 of the first partition wall layer L1 may be undercut with respect to the inner surfaces S-L2 of the second partition wall layer L2. Portions of the second partition wall layer L2 that protrude from the first partition wall layer L1 toward the emissive areas PXA-B, PXA-G, and PXA-R may define the tip portions.

In an embodiment, the first partition wall layer L1 may include a conductive material (e.g., an electrically conductive material). The conductive material may include metal, transparent conductive oxide (TCO), or a combination thereof. For example, the metal may include gold (Au), silver (Ag), aluminum (AI), magnesium (Mg), lithium (Li), molybdenum (Mo), titanium (Ti), copper (Cu), and/or an alloy. The transparent conductive oxide may include indium tin oxide (ITO), indium zinc oxide (IZO), zinc oxide, indium oxide, indium gallium oxide, indium gallium zinc oxide (IGZO), and/or aluminum zinc oxide.

In an embodiment, the second partition wall layer L2 may include an organic material and may include a light absorbing material. For example, the second partition wall layer L2 may include graphite, diamond, and/or a polymer. The second partition wall layer L2 may have a wide range of refractive index.

The partition wall PW may receive a bias voltage. The cathode CE may be electrically connected to the partition wall PW by making direct contact with the partition wall PW and may receive the bias voltage.

According to the present disclosure, the plurality of emissive layers EL1, EL2, and EL3 may be subjected to patterning and deposited in pixel units by the tip portions defined in the partition wall PW. For example, the plurality of emissive layers EL1, EL2, and EL3 may be commonly formed using an open mask, but may be easily divided in pixel units by the partition wall PW.

In contrast, when a plurality of emissive layers are subjected to patterning through a fine metal mask (FMM), a spacer for support that protrudes from a partition wall has to be provided to support the fine metal mask. Furthermore, the fine metal mask may be spaced, by the height of the partition wall and the spacer, apart from a base surface on which the patterning is performed, and therefore there may be a limitation in the implementation of high resolution. In addition, because the fine metal mask is brought into contact with the spacer, foreign matter may remain on the spacer after the patterning process of the plurality of emissive layers, and/or the spacer may be damaged by a dent defect of the fine metal mask. Accordingly, a defective display panel may be formed.

Because the display panel DP includes the partition wall PW, the physical separation between the light emitting elements ED1, ED2, and ED3 may be easily achieved. Accordingly, current leakage and/or operating errors between the adjacent emissive areas PXA-B, PXA-G, and PXA-R may be prevented or reduced.

For example, by making the plurality of emissive layers EL1, EL2, and EL3 subject to patterning without a mask in contact with an internal component in the display area DA (refer to FIG. 2), a defect rate may be reduced, and thus the display panel DP having improved process reliability may be provided. Because the patterning is possible even without the separate spacer for support that protrudes from the partition wall PW, the areas of the emissive areas PXA-B, PXA-G, and PXA-R may be scaled down, and thus the display panel DP capable of easily implementing high resolution may be provided.

Furthermore, in the manufacture of the large-area display panel DP, the manufacture of a large-area mask may be omitted. Accordingly, process costs may be reduced, and the display panel DP may not be affected by defects that are likely to occur in the large-area mask. Thus, the display panel DP having improved process reliability may be provided.

According to an embodiment of the present disclosure, the display panel DP may further include capping patterns. The capping patterns may be provided in the partition wall openings OP1-P, OP2-P, and OP3-P, respectively. The capping patterns may be subjected to patterning by the tip portions formed in the partition wall PW.

The dummy patterns D1, D2, and D3 may be on the partition wall PW. The dummy patterns D1, D2, and D3 may include the first dummy pattern D1, the second dummy pattern D2, and the third dummy pattern D3.

Each of the dummy patterns D1, D2, and D3 may include an organic material. For example, the first to third dummy patterns D1, D2, and D3 may include the same materials as the first to third emissive layers EL1, EL2, and EL3, respectively. One dummy pattern may be concurrently (e.g., simultaneously) formed with the corresponding emissive layer through one process and may be separated from the corresponding emissive layer by the undercut shape of the partition wall PW.

First to third dummy openings OP1-D, OP2-D, and OP3-D may be defined in the first to third dummy patterns D1, D2, and D3, respectively. The first to third dummy openings OP1-D, OP2-D, and OP3-D may correspond to the first to third light emitting openings OP1-E, OP2-E, and OP3-E, respectively. When viewed from above the plane, the first to third dummy patterns D1, D2, and D3 may surround the first to third emissive areas PXA-B, PXA-G, and PXA-R, respectively, and each of the first to third dummy patterns D1, D2, and D3 may have a closed-line shape.

Although FIG. 10 illustrates an example that the inner surface of the first dummy pattern D1 that defines the first dummy opening OP1-D is aligned with the inner surface of the second partition wall layer L2 that defines the second area of the first partition wall opening OP1-P, the present disclosure is not limited thereto, and the first dummy pattern D1 may cover the inner surface of the second partition wall layer L2. The description thereof may be similarly applied to the second dummy pattern D2 and the third dummy pattern D3.

The color filter layer CFL may be on the thin film encapsulation layer TFE. The color filter layer CFL may include a first color filter CF1 corresponding to the first emissive area PXA-B, a second color filter CF2 corresponding to the second emissive area PXA-G, and a third color filter CF3 corresponding to the third emissive area PXA-R. In embodiments, the color filter layer CFL may further include a light blocking pattern. The first color filter CF1 transmits the light of the first color among the light of the first color, the light of the second color, and the light of the third color generated by the display panel DP, the second color filter CF2 transmits the light of the second color among the light of the first color, the light of the second color, and the light of the third color generated by the display panel DP, and the third color filter CF3 transmits the light of the third color among the light of the first color, the light of the second color, and the light of the third color generated by the display panel DP.

Each of the first to third color filters CF1, CF2, and CF3 may include a photosensitive polymer resin and a colorant. In this specification, the colorant includes a pigment and/or a dye. A red colorant includes a red pigment and/or a red dye, a green colorant includes a green pigment and/or a green dye, and a blue colorant includes a blue pigment and/or a blue dye.

The color filter layer CFL may include a planarization layer PZL on the first to third color filters CF1, CF2, and CF3. The planarization layer PZL may include an organic material.

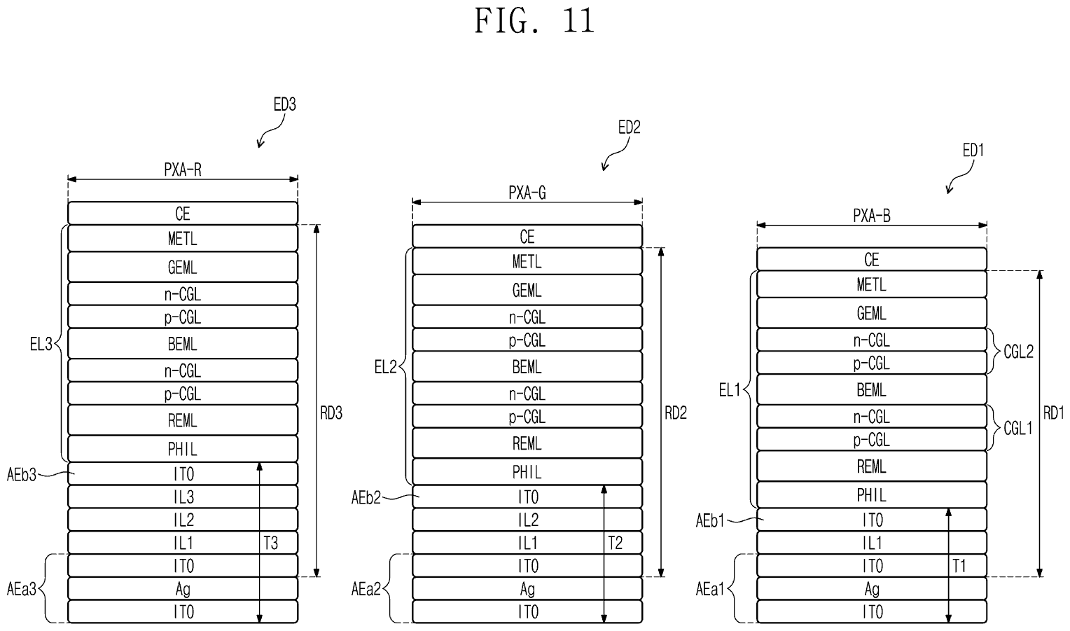

FIG. 11 is a cross-sectional view illustrating a comparison of the first to third light emitting elements according to an embodiment of the present disclosure. In describing FIG. 11, the components described with reference to FIG. 10 will be assigned with the same reference numerals, and redundant description thereof may not be repeated.

Referring to FIG. 11, the first to third emissive layers EL1, EL2, and EL3 may include a hole injection layer PHIL, a first emissive layer REML, a first charge generation layer CGL1, a second emissive layer BEML, a second charge generation layer CGL2, a third emissive layer GEML, and an electron transport layer METL. In an embodiment of the present disclosure, the hole injection layer PHIL and the electron transport layer METL may be omitted.

The hole injection layer PHIL may include a hole injection/transport material doped with a P-type dopant. The electron transport layer METL may include an electron injection/transport material including metal. Each of the first charge generation layer CGL1 and the second charge generation layer CGL2 may include a first-type charge generation layer nCGL and a second-type charge generation layer pCGL stacked on each other. The first-type charge generation layer nCGL may be an n-type charge generation layer, and the second-type charge generation layer pCGL may be a p-type charge generation layer.

The first emissive layer REML may generate the light of the first color, the second emissive layer BEML may generate the light of the second color, and the third emissive layer GEML may generate the light of the third color. The light of the first color may be light having a longer wavelength than the light of the second color and the light of the third color. The light of the third color may be light having a shorter wavelength than the light of the first color and the light of the second color.

Each of the first-first anode AEa1, the first-second anode AEa2, and the first-third anode AEa3 may include a plurality of layers including indium tin oxide (ITO) and silver (Ag). For example, each of the first-first anode AEa1, the first-second anode AEa2, and the first-third anode AEa3 may include a first layer including ITO, a reflective layer that is on the first layer and that includes Ag, and a second layer that is on the reflective layer and that includes ITO. Each of the first-first anode AEa1, the first-second anode AEa2, and the first-third anode AEa3 may be referred to as a first anode or a lower anode.

Each of the second-first anode AEb1, the second-second anode AEb2, and the second-third anode AEb3 may include a layer including ITO. Each of the second-first anode AEb1, the second-second anode AEb2, and the second-third anode AEb3 may be referred to as a second anode or an upper anode.

The first insulating layer IL1 may be between the first-first anode AEa1 and the second-first anode AEb1. The thickness from the first-first anode AEa1 to the second-first anode AEb1 may be defined as a first thickness T1.

The first insulating layer IL1 and the second insulating layer IL2 may be between the first-second anode AEa2 and the second-second anode AEb2. The thickness from the first-second anode AEa2 to the second-second anode AEb2 may be defined as a second thickness T2.

The first insulating layer IL1, the second insulating layer IL2, and the third insulating layer IL3 may be between the first-third anode AEa3 and the second-third anode AEb3. The thickness from the first-third anode AEa3 to the second-third anode AEb3 may be defined as a third thickness T3.

Due to the first to third insulating layers IL1, IL2, and IL3, the second thickness T2 may be greater than the first thickness T1, and the third thickness T3 may be greater than the second thickness T2.

Each of first to third resonance distances RD1, RD2, and RD3 may be defined as the distance from the upper surface of the corresponding reflective layer to the lower surface of the cathode CE. The second resonance distance RD2 may be longer than the first resonance distance RD1, and the third resonance distance RD3 may be longer than the second resonance distance RD2.

The first to third resonance distances RD1, RD2, and RD3 may be determined by the first to third thicknesses T1, T2, and T3.

The third resonance distance RD3 of the third light emitting element ED3 that generates light having the longest wavelength may be the longest.

Because the first to third light emitting elements ED1, ED2, and ED3 include the first to third emissive layers EL1, EL2, and EL3 and the cathode CE formed by the same process, only the thicknesses T1, T2, and T3 may be substantially different from one another. Therefore, the difference between the first resonance distance RD1 and the second resonance distance RD2 may be substantially the same as the difference between the first thickness T1 and the second thickness T2. For the same reason, the difference between the second resonance distance RD2 and the third resonance distance RD3 may be substantially the same as the difference between the second thickness T2 and the third thickness T3.

Among the first to third light emitting elements ED1, ED2, and ED3, the first light emitting element ED1 having the shortest first resonance distance RD1 may increase the light emission efficiency of the light of the first color that has the shortest wavelength. Among the first to third light emitting elements ED1, ED2, and ED3, the third light emitting element ED3 having the longest third resonance distance RD3 may increase the light emission efficiency of the light of the third color that has the longest wavelength. As a result, the light emission efficiency of each of the first to third light emitting elements ED1, ED2, and ED3 may be increased.

Although the first to third light emitting elements ED1, ED2, and ED3 having the first to third resonance distances RD1, RD2, and RD3 are illustrated as an example, some of the light emitting elements may have the same resonance distance to increase process efficiency. For example, the first light emitting element ED1 and the second light emitting element ED2 may be configured to have the same resonance distance, and the second light emitting element ED2 and the third light emitting element ED3 may be configured to have the same resonance distance.

According to embodiments of the present disclosure, the thicknesses of the insulating layers between the first anodes AEa1, AEa2, and AEa3 and the second anodes AEb1, AEb2, and AEb3 may be different for the plurality of pixels that emit light of different colors. Due to this, the light emission efficiency may be improved. Accordingly, an electronic device manufacturing method having improved display quality may be provided.

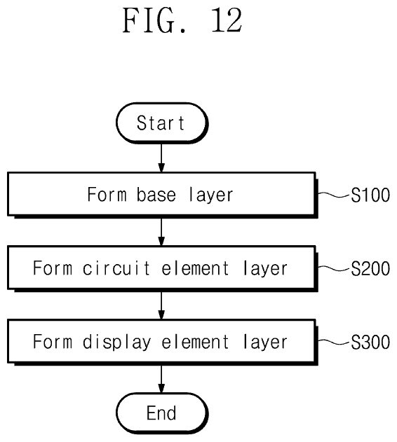

FIGS. 12 and 13 are flowcharts illustrating an electronic device manufacturing method according to an embodiment of the present disclosure.

Referring to FIGS. 10, 12, and 13, the electronic device manufacturing method may include forming the base layer SUB (S100), forming the circuit element layer DP-CL on the base layer SUB (S200), and forming the display element layer DP-OLED on the circuit element layer DP-CL (S300).

The forming the display element layer DP-OLED (S300) may include forming the first anodes AEa1, AEa2, and AEa3 in the first emissive area PXA-B, the second emissive area PXA-G, and the third emissive area PXA-R, respectively (S310), forming the first insulating layer IL1 on the first anodes AEa1, AEa2, and AEa3 (S320), forming a first etching stopper layer on the first insulating layer IL1 (S330), forming the second insulating layer IL2 on the first etching stopper layer (S340), forming a second etching stopper layer on the second insulating layer IL2 (S350), forming the third insulating layer IL3 on the second etching stopper layer (S360), etching the first to third insulating layers IL1, IL2, and IL3 (S370), etching the first etching stopper layer and the second etching stopper layer (S380), and forming the second anodes AEb1, AEb2, and AEb3 over the first anodes AEa1, AEa2, and AEa3 (S390). Description thereabout will be given below.

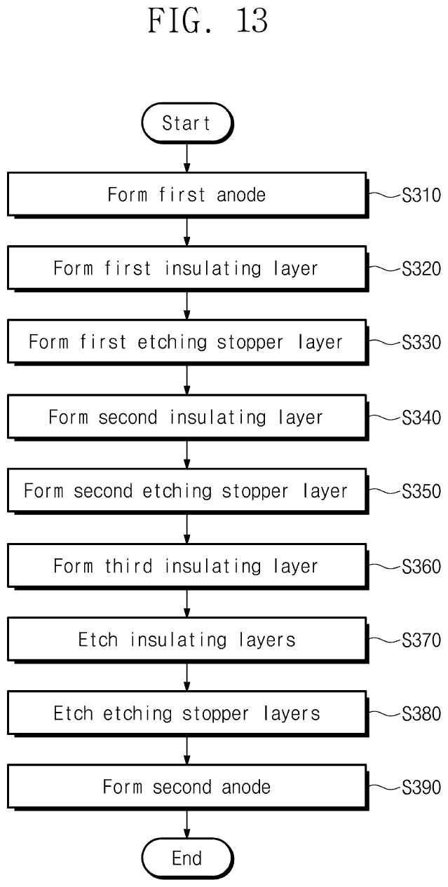

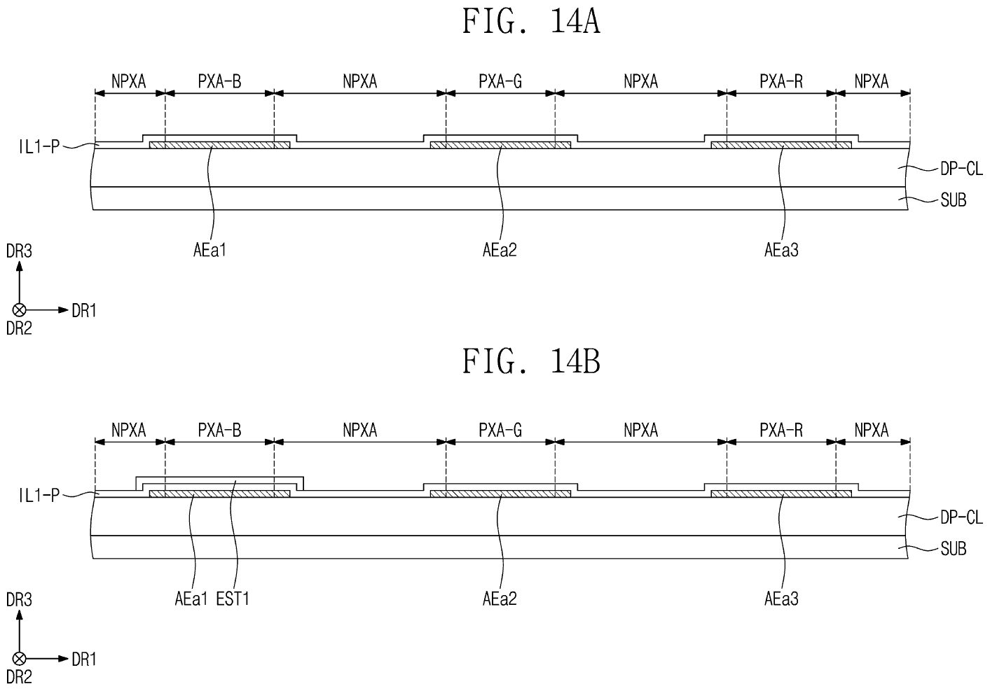

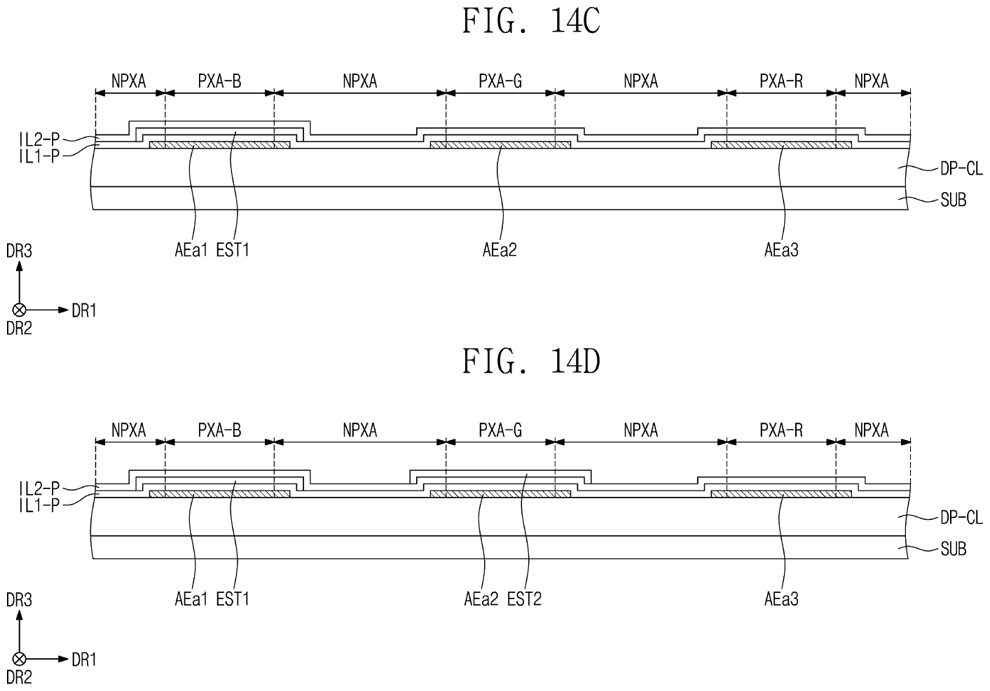

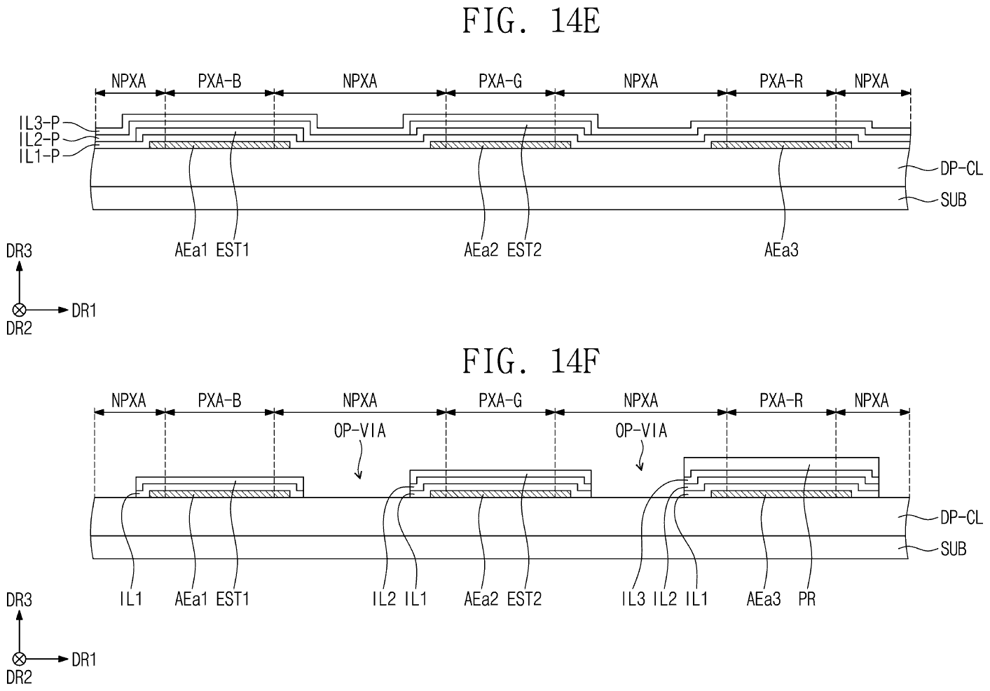

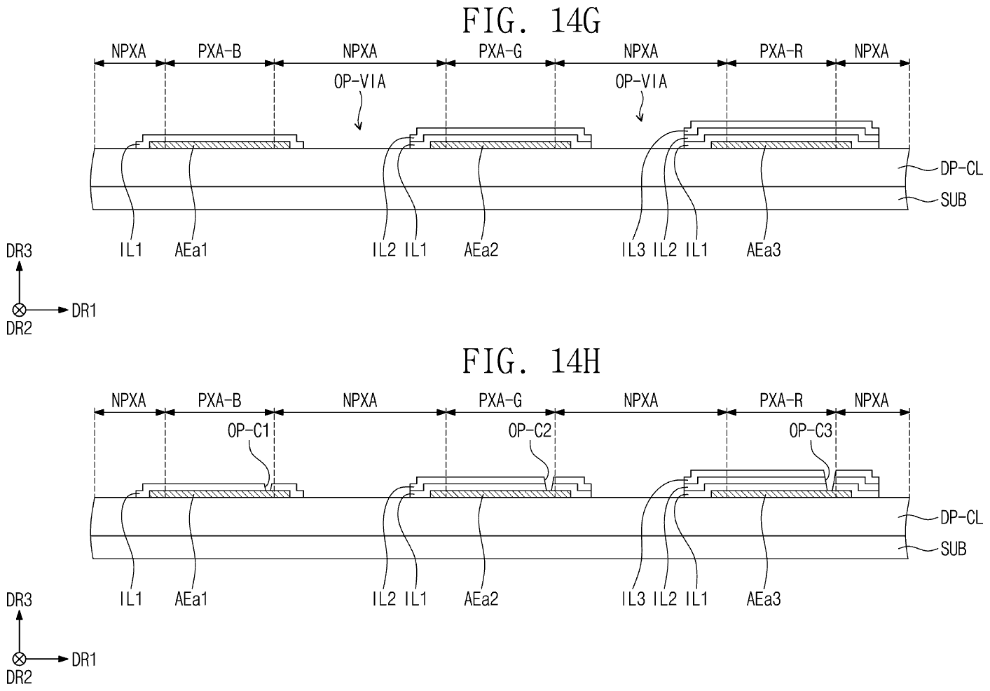

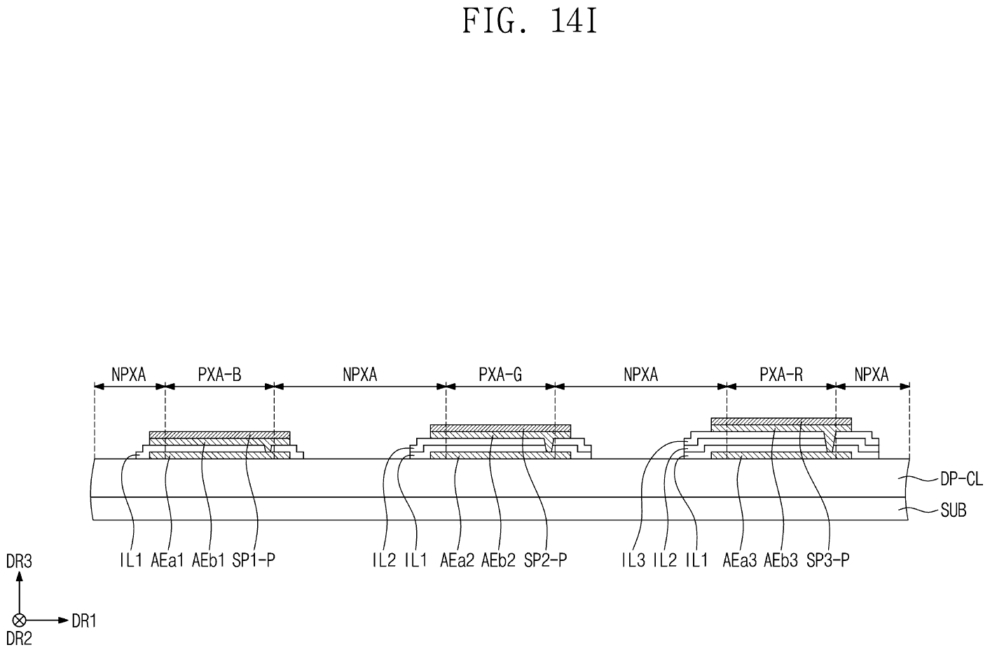

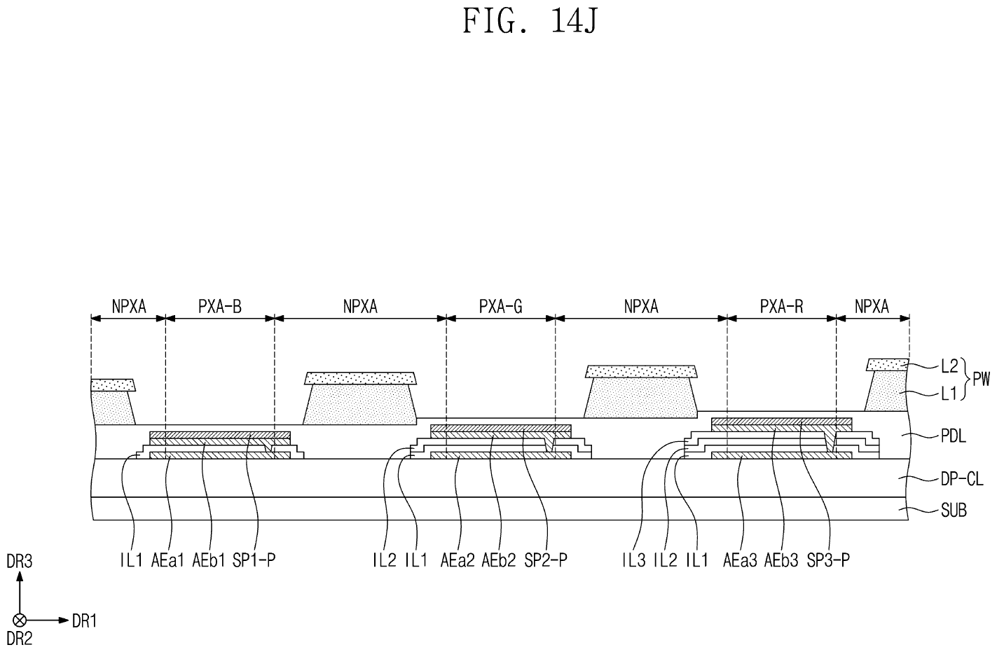

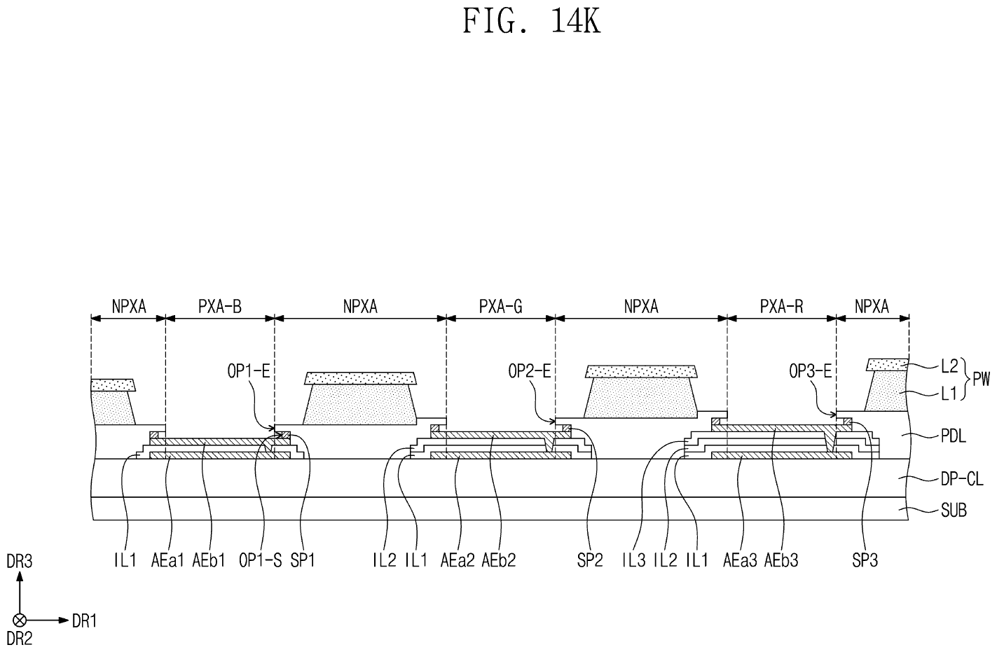

FIG. 14A is a cross-sectional view illustrating the forming the first insulating layer according to an embodiment of the present disclosure.

Referring to FIGS. 12 to 14A, the circuit element layer DP-CL may be formed on the base layer SUB (S200). The display element layer DP-OLED may be formed on the circuit element layer DP-CL (S300).

In the areas corresponding to the first to third emissive areas PXA-B, PXA-G, and PXA-R, respectively, the first anodes AEa1, AEa2, and AEa3 may be formed on the circuit element layer DP-CL (S310).

After a first preliminary anode is deposited on the circuit element layer DP-CL, patterns may be formed using a photoresist layer in the areas corresponding to the first to third emissive areas PXA-B, PXA-G, and PXA-R. Thereafter, the first anodes AEa1, AEa2, and AEa3 may be formed using wet etching.

The forming the first anodes AEa1, AEa2, and AEa3 (S310) according to an embodiment of the present disclosure may further include curing indium tin oxide. The curing the indium tin oxide may be performed through thermal curing.

Each of the first anodes AEa1, AEa2, and AEa3 may include a conductive material (e.g., an electrically conductive material) having reflectivity. For example, each of the first anodes AEa1, AEa2, and AEa3 may have a three-layer structure of ITO/Ag/ITO.

After the first anodes AEa1, AEa2, and AEa3 are formed, the first insulating layer IL1-P may be formed (S320). The first insulating layer IL1-P may be formed using chemical vapor deposition (CVD).

The first insulating layer IL1-P may cover the first anodes AEa1, AEa2, and AEa3. The first insulating layer IL1-P may include silicon oxide (SiOx).

FIG. 14B is a cross-sectional view illustrating the forming the first etching stopper layer according to an embodiment of the present disclosure. In describing FIG. 14B, the components described with reference to FIG. 14A will be assigned with the same reference numerals, and redundant description thereof may not be repeated.

Referring to FIGS. 12 to 14B, the first etching stopper layer EST1 may be formed in the area corresponding to the first emissive area PXA-B (S330).

The first etching stopper layer EST1 may be deposited through sputtering, and patterns may be formed using a photoresist layer in the area corresponding to the first emissive area PXA-B. Thereafter, the first etching stopper layer EST1 may be formed using wet etching.

The first etching stopper layer EST1 may include a material that does not react with the etching solution of the first insulating layer IL1-P. For example, the first etching stopper layer EST1 may include indium zinc oxide (IZO).

FIG. 14C is a cross-sectional view illustrating the forming the second insulating layer according to an embodiment of the present disclosure. In describing FIG. 14C, the components described with reference to FIGS. 14A and 14B will be assigned with the same reference numerals, and redundant description thereof may not be repeated.

Referring to FIGS. 12 to 14C, the second insulating layer IL2-P may be formed on the first insulating layer IL1-P (S340). The second insulating layer IL2-P may be formed using chemical vapor deposition (CVD).

The second insulating layer IL2-P may cover the first etching stopper layer EST1. The second insulating layer IL2-P may include substantially the same material as the first insulating layer IL1-P. For example, the second insulating layer IL2-P may include silicon oxide (SiOx).

FIG. 14D is a cross-sectional view illustrating the forming the second etching stopper layer according to an embodiment of the present disclosure. In describing FIG. 14D, the components described with reference to FIGS. 14A to 14C will be assigned with the same reference numerals, and redundant description thereof may not be repeated.

Referring to FIGS. 12 to 14D, the second etching stopper layer EST2 may be formed in the area corresponding to the second emissive area PXA-G (S350).

The second etching stopper layer EST2 may be formed by substantially the same process as the first etching stopper layer EST1. The second etching stopper layer EST2 may include substantially the same material as the first etching stopper layer EST1. For example, the second etching stopper layer EST2 may include indium zinc oxide (IZO).

FIG. 14E is a cross-sectional view illustrating the forming the third insulating layer according to an embodiment of the present disclosure. In describing FIG. 14E, the components described with reference to FIGS. 14A to 14D will be assigned with the same reference numerals, and redundant description thereof may not be repeated.

Referring to FIGS. 12 to 14E, the third insulating layer IL3-P may be formed on the second insulating layer IL2-P (S360). The third insulating layer IL3-P may be formed using chemical vapor deposition (CVD).

The third insulating layer IL3-P may cover the second etching stopper layer EST2. The third insulating layer IL3-P may include substantially the same material as the first insulating layer IL1-P and the second insulating layer IL2-P. The third insulating layer IL3-P may include silicon oxide (SiOx).

FIG. 14F is a cross-sectional view illustrating the etching the insulating layers according to an embodiment of the present disclosure. In describing FIG. 14F, the components described with reference to FIGS. 14A to 14E will be assigned with the same reference numerals, and redundant description thereof may not be repeated.

Referring to FIGS. 12 to 14F, photoresist PR may be applied to the third insulating layer IL3-P in the area corresponding to the third emissive area PXA-R. Thereafter, the plurality of insulating layers IL1-P, IL2-P, and IL3-P may be etched using dry etching (S370).

When viewed from above the plane, at least portions of the first to third insulating layers IL1-P, IL2-P, and IL3-P other than the areas that overlap the photoresist PR, the first etching stopper layer EST1, and the second etching stopper layer EST2 may be removed by the dry etching process.

Among the plurality of insulating layers IL1-P, IL2-P, and IL3-P stacked in the first emissive area PXA-B, the first insulating layer IL1-P under the first etching stopper layer EST1 may not be etched. The first insulating layer IL1 may be formed on the first-first anode AEa1.

Among the plurality of insulating layers IL1-P, IL2-P, and IL3-P stacked in the second emissive area PXA-G, the first insulating layer IL1-P and the second insulating layer IL2-P under the second etching stopper layer EST2 may not be etched. The first insulating layer IL1 and the second insulating layer IL2 may be formed on the first-second anode AEa2.

The plurality of insulating layers IL1-P, IL2-P, and IL3-P stacked in the third emissive area PXA-R may not be etched by the photoresist PR. The first insulating layer IL1, the second insulating layer IL2, and the third insulating layer IL3 may be formed on the first-third anode AEa3.

The peripheral area NPXA may be defined between the areas where the first to third emissive areas PXA-B, PXA-G, and PXA-R are defined.

When viewed from above the plane, the area that does not overlap the etching stopper layers EST1 and EST2 and the photoresist PR may be provided in the peripheral area NPXA.

The first to third insulating layers IL1, IL2, and IL3 provided in the area that does not overlap the etching stopper layers EST1 and EST2 and the photoresist PR may be etched.

Due to this, a plurality of opening patterns OP-VIA may be formed between the first to third emissive areas PXA-B, PXA-G, and PXA-R. When viewed from above the plane (e.g., in a plan view), the plurality of opening patterns OP-VIA may overlap the peripheral area NPXA.

According to embodiments of the present disclosure, the circuit element layer DP-CL may be exposed by the plurality of opening patterns OP-VIA during the manufacturing process of the electronic device. Outgas generated by residual moisture in the lower organic film of the circuit element layer DP-CL may be easily released. A film lifting phenomenon caused by the outgas may be reduced. In embodiments, damage to the light emitting element ED (refer to FIG. 9) or the cathode CE (refer to FIG. 9) caused by the outgas may be prevented, eliminated, or reduced. Accordingly, the electronic device manufacturing method having improved reliability may be provided.

FIG. 14G is a cross-sectional view illustrating the etching the etching stopper layers according to an embodiment of the present disclosure. In describing FIG. 14G, the components described with reference to FIGS. 14A to 14F will be assigned with the same reference numerals, and redundant description thereof may not be repeated.

Referring to FIGS. 12 to 14G, the first etching stopper layer EST1 and the second etching stopper layer EST2 may be etched (S380). A wet etching process may be performed after the dry etching process. The first etching stopper layer EST1 and the second etching stopper layer EST2 may be removed by the wet etching process.

The first insulating layer IL1 may be on the first-first anode AEa1 provided in the first emissive area PXA-B.

The first insulating layer IL1 and the second insulating layer IL2 may be on the first-second anode AEa2 provided in the second emissive area PXA-G.

The first insulating layer IL1, the second insulating layer IL2, and the third insulating layer IL3 may be provided on the first-third anode AEa3 provided in the third emissive area PXA-R.

FIG. 14H is a cross-sectional view illustrating forming a contact hole according to an embodiment of the present disclosure. In describing FIG. 14H, the components described with reference to FIGS. 14A to 14G will be assigned with the same reference numerals, and redundant description thereof may not be repeated.

Referring to FIGS. 12 to 14H, a first contact hole OP-C1 exposing at least a portion of the first-first anode AEa1 may be formed in the first insulating layer IL1 provided in the first emissive area PXA-B.

A second contact hole OP-C2 exposing at least a portion of the first-second anode AEa2 may be formed in the first insulating layer IL1 and the second insulating layer IL2 that are provided in the second emissive area PXA-G.

A third contact hole OP-C3 exposing at least a portion of the first-third anode AEa3 may be formed in the first insulating layer IL1, the second insulating layer IL2, and the third insulating layer IL3 that are provided in the third emissive area PXA-R.

FIG. 14I is a cross-sectional view illustrating the forming the second anode according to an embodiment of the present disclosure. In describing FIG. 14I, the components described with reference to FIGS. 14A to 14H will be assigned with the same reference numerals, and redundant description thereof may not be repeated.

Referring to FIGS. 12 to 14I, the second anodes AEb1, AEb2, and AEb3 may be formed in the areas corresponding to the first to third emissive areas PXA-B, PXA-G, and PXA-R (S390).

Each of the second anodes AEb1, AEb2, and AEb3 may include a conductive material (e.g., an electrically conductive material) having transparency. For example, each of the second anodes AEb1, AEb2, and AEb3 may include ITO.

The second-first anode AEb1 provided in the first emissive area PXA-B may be on the first insulating layer IL1. The second-first anode AEb1 may be connected with the first-first anode AEa1 through the first contact hole OP-C1. When viewed from above the plane (e.g., in a plan view), the second-first anode AEb1 may overlap the first-first anode AEa1.

The first sacrificial pattern SP1-P may be formed on the second-first anode AEb1. The first sacrificial pattern SP1-P may include IZO.

The second-second anode AEb2 provided in the second emissive area PXA-G may be on the first insulating layer IL1 and the second insulating layer IL2. The second-second anode AEb2 may be connected with the first-second anode AEa2 through the second contact hole OP-C2. When viewed from above the plane, the second-second anode AEb2 may overlap the first-second anode AEa2.

The second sacrificial pattern SP2-P may be formed on the second-second anode AEb2. The second sacrificial pattern SP2-P may include IZO.

The second-third anode AEb3 provided in the third emissive area PXA-R may be on the first insulating layer IL1, the second insulating layer IL2, and the third insulating layer IL3. The second-third anode AEb3 may be connected with the first-third anode AEa3 through the third contact hole OP-C3. When viewed from above the plane (e.g., in a plan view), the second-third anode AEb3 may overlap the first-third anode AEa3.

The third sacrificial pattern SP3-P may be formed on the second-third anode AEb3. The third sacrificial pattern SP3-P may include IZO.

FIGS. 14J and 14K are cross-sectional views illustrating the electronic device manufacturing method according to an embodiment of the present disclosure. In describing FIGS. 14J and 14K, the components described with reference to FIGS. 14A to 14I will be assigned with the same reference numerals, and redundant description thereof may not be repeated.

Referring to FIGS. 14J and 14K, the pixel defining layer PDL may be formed on the sacrificial patterns SP1-P, SP2-P, and SP3-P and the circuit element layer DP-CL.

The partition wall PW may be formed on the pixel defining layer PDL. The partition wall PW may include the first partition wall layer L1 and the second partition wall layer L2.

The pixel defining layer PDL and the first sacrificial pattern SP1 that overlap the first emissive area PXA-B may be etched. The first light emitting opening OP1-E may be formed in the pixel defining layer PDL. At least a portion of the second-first anode AEb1 may be exposed.

The pixel defining layer PDL and the second sacrificial pattern SP2 that overlap the second emissive area PXA-G may be etched. The second light emitting opening OP2-E may be formed in the pixel defining layer PDL. At least a portion of the second-second anode AEb2 may be exposed.

The pixel defining layer PDL and the third sacrificial pattern SP3 that overlap the third emissive area PXA-R may be etched. The third light emitting opening OP3-E may be formed in the pixel defining layer PDL. At least a portion of the second-third anode AEb3 may be exposed.

Thereafter, the emissive layers EL1, EL2, and EL3 may be formed, and the cathode CE may be formed to cover the emissive layers EL1, EL2, and EL3.

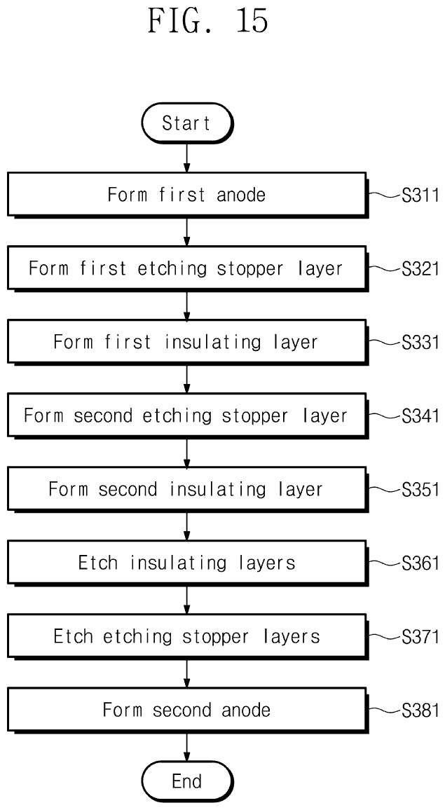

FIG. 15 is a flowchart illustrating an electronic device manufacturing method according to an embodiment of the present disclosure.

Referring to FIG. 15, when the electronic device manufacturing method is compared with the electronic device manufacturing method illustrated in FIG. 13, the first insulating layer IL1 (refer to FIG. 10) may be omitted. Due to this, the second-first anode AEb1 provided in the first emissive area PXA-B may be directly on the first-first anode AEa1. For example, the first-first anode AEa1 and the second-first anode AEb1 provided in the first emissive area PXA-B may make direct contact with each other.

The electronic device manufacturing method may include forming the first anode (S311), forming the first etching stopper layer (S321), forming the first insulating layer (S331), forming the second etching stopper layer (S341), forming the second insulating layer (S351), etching the insulating layers (S361), etching the etching stopper layers (S371), and forming the second anode (S381).

According to embodiments of the present disclosure, in the electronic device manufacturing method, the forming the first insulating layer IL1 (refer to FIG. 10) may be omitted. Due to this, the process step may be simplified. Accordingly, the electronic device manufacturing method having improved reliability may be provided.

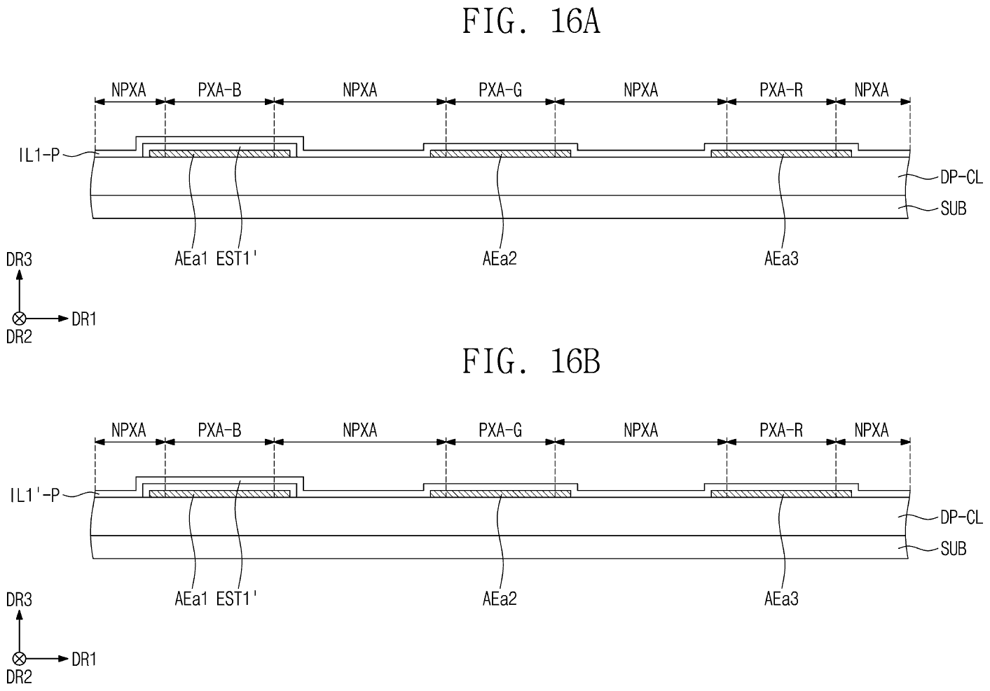

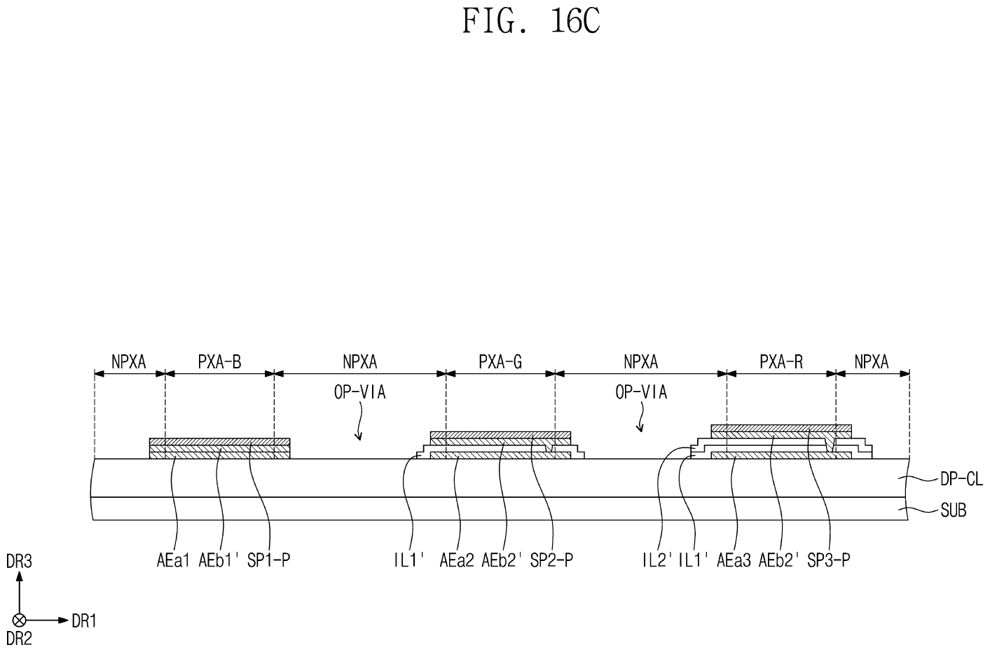

FIG. 16A is a cross-sectional view illustrating the forming the first etching stopper layer according to an embodiment of the present disclosure. In describing FIG. 16A, the components described with reference to FIG. 14B will be assigned with the same reference numerals, and redundant description thereof may not be repeated.

Referring to FIGS. 15 and 16A, the first etching stopper layer EST1′ may be formed on the first-first anode AEa1 provided in the first emissive area PXA-B (S321).

FIG. 16B is a cross-sectional view illustrating the forming the first insulating layer according to an embodiment of the present disclosure. In describing FIG. 16B, the components described with reference to FIG. 14C will be assigned with the same reference numerals, and redundant description thereof may not be repeated.

Referring to FIGS. 15 and 16B, the first insulating layer IL1′-P may be formed on the circuit element layer DP-CL (S331). The first insulating layer IL1′-P may cover the first etching stopper layer EST1′.

FIG. 16C is a cross-sectional view illustrating the forming the second anode according to an embodiment of the present disclosure. In describing FIG. 16C, the components described with reference to FIG. 14I will be assigned with the same reference numerals, and redundant description thereof may not be repeated.

Referring to FIGS. 15 and 16C, the second etching stopper layer may be formed on the first insulating layer IL1′-P provided in the second emissive area PXA-G (S341). The second insulating layer may be formed on the first insulating layer IL1′-P (S351). The plurality of etching layers may be etched (S361). Thereafter, the etching stopper layers may be etched (S371).

The second-first anode AEb1 provided in the first emissive area PXA-B may be directly on the first-first anode AEa1.

The second-second anode AEb2 provided in the second emissive area PXA-G may be on the first insulating layer IL1′. The second-second anode AEb2 may be connected with the first-second anode AEa2 by a first contact hole formed in the first insulating layer IL1′. When viewed from above the plane (e.g., in a plan view), the second-second anode AEb2 may overlap the first-second anode AEa2.

The second sacrificial pattern SP2-P may be formed on the second-second anode AEb2. The second sacrificial pattern SP2-P may include IZO.

The second-third anode AEb3 provided in the third emissive area PXA-R may be on the second insulating layer IL2′. The second-third anode AEb3 may be connected with the first-third anode AEa3 by a second contact hole formed in the first insulating layer IL1′ and the second insulating layer IL2′.

When viewed from above the plane (e.g., in a plan view), the second-third anode AEb3 may overlap the first-third anode AEa3.

The third sacrificial pattern SP3-P may be formed on the second-third anode AEb3. The third sacrificial pattern SP3-P may include IZO.

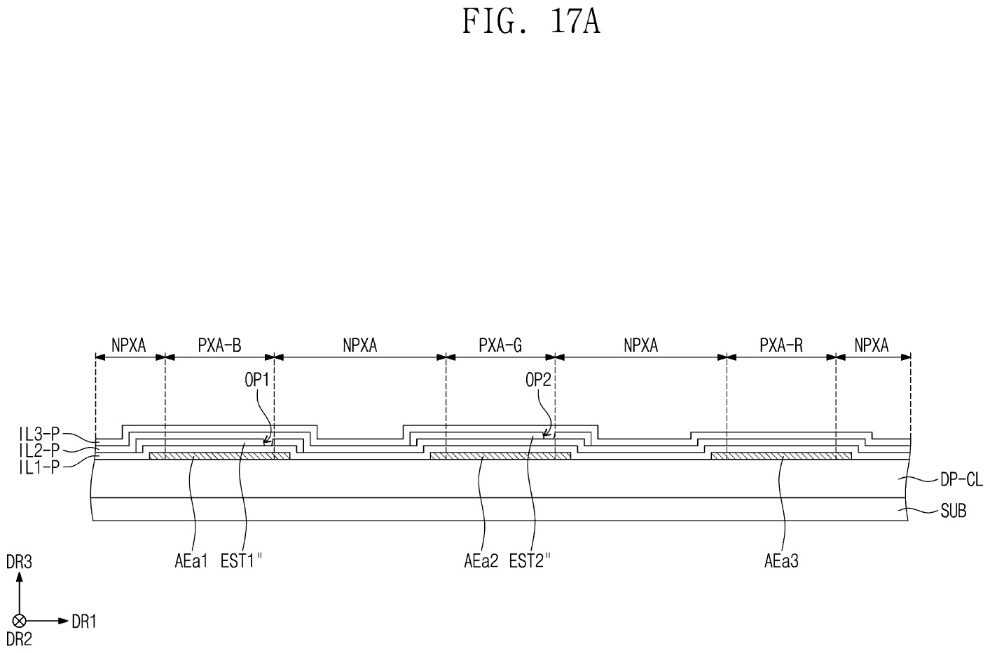

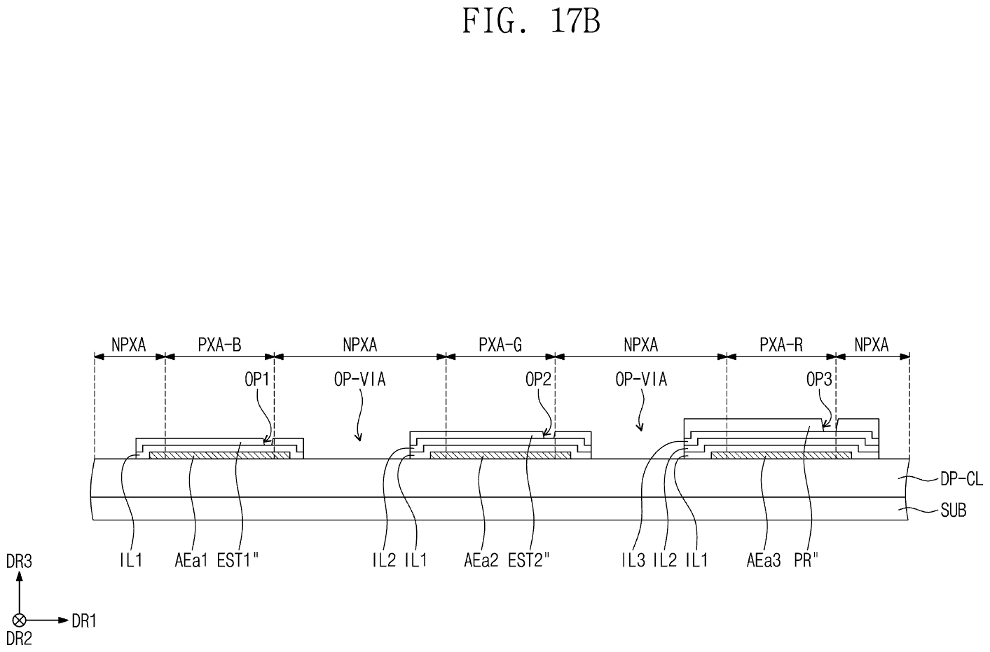

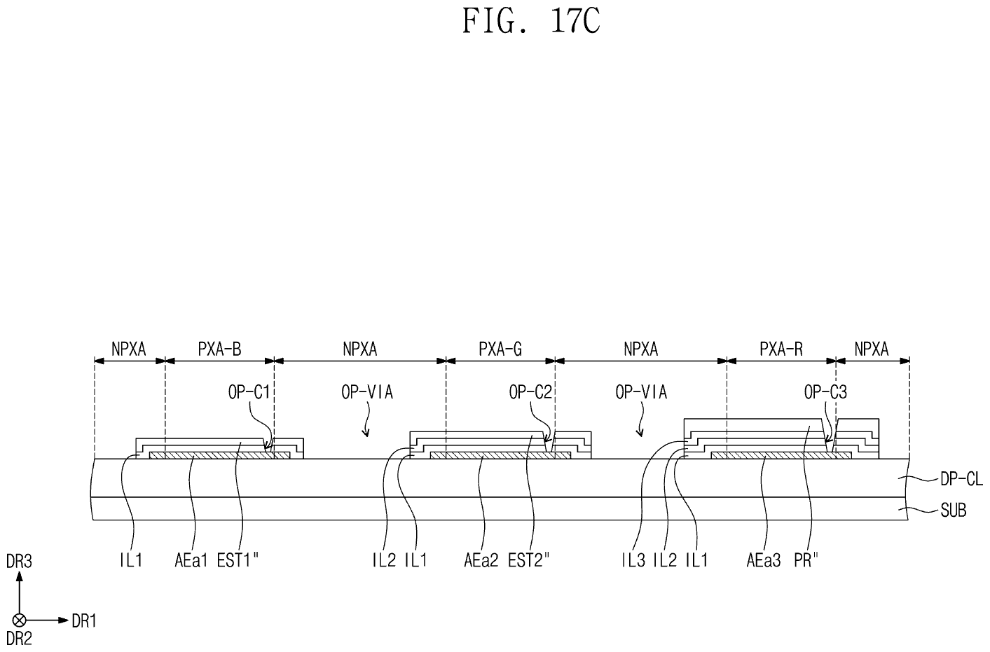

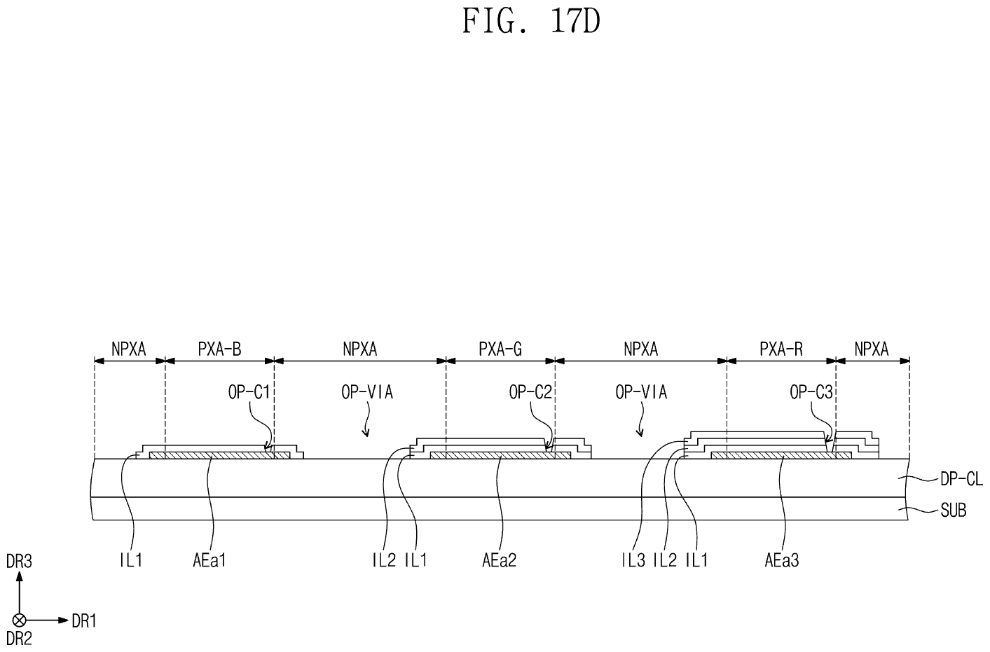

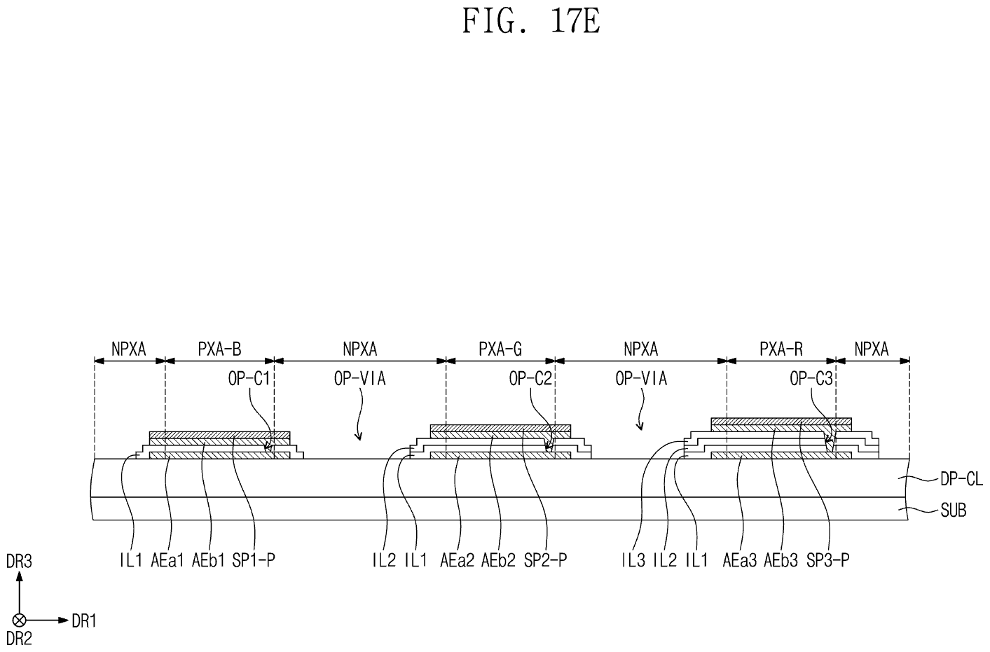

FIG. 17A is a cross-sectional view illustrating an electronic device manufacturing method according to an embodiment of the present disclosure. In describing FIG. 17A, the components described with reference to FIG. 14E will be assigned with the same reference numerals, and redundant description thereof may not be repeated.

Referring to FIG. 17A, a contact hole OP1 may be formed in advance in a first etching stopper layer EST1″. A contact hole OP2 may be formed in advance in a second etching stopper layer EST2″

FIGS. 17B and 17C are cross-sectional views illustrating the electronic device manufacturing method according to an embodiment of the present disclosure. In describing FIGS. 17B and 17C, the components described with reference to FIG. 14F will be assigned with the same reference numerals, and redundant description thereof may not be repeated.

Referring to FIGS. 17A, 17B, and 17C, photoresist PR″ may be applied to the third insulating layer IL3-P in the area corresponding to the third emissive area PXA-R. A contact hole OP3 may be formed in advance in the photoresist PR″. Thereafter, the plurality of insulating layers IL1-P, IL2-P, and IL3-P may be etched using dry etching.

The first contact hole OP-C1 may be formed by the contact hole OP1 during the dry etching process before the first etching stopper layer EST1″ is removed.

The second contact hole OP-C2 may be formed by the contact hole OP2 during the dry etching process before the second etching stopper layer EST2″ is removed.

The third contact hole OP-C3 may be formed by the contact hole OP3 during the dry etching process before the photoresist PR″ is removed.

According to the present disclosure, in the electronic device manufacturing method, the forming the contact holes OP-C1, OP-C2, and OP-C3 may be omitted. A mask to form the contact holes OP-C1, OP-C2, and OP-C3 may be unnecessary. Due to this, the process step may be simplified. Accordingly, the electronic device manufacturing method having improved reliability may be provided.

FIG. 17D is a cross-sectional view illustrating the electronic device manufacturing method according to an embodiment of the present disclosure. In describing FIG. 17D, the components described with reference to FIG. 14G will be assigned with the same reference numerals, and redundant description thereof may not be repeated.

Referring to FIGS. 17C and 17D, a wet etching process may be performed after the dry etching process. The first etching stopper layer EST1″, the second etching stopper layer EST2″, and the photoresist PR″ may be removed by the wet etching process.

FIG. 17E is a cross-sectional view illustrating the electronic device manufacturing method according to an embodiment of the present disclosure. In describing FIG. 17E, the components described with reference to FIG. 14I will be assigned with the same reference numerals, and redundant description thereof may not be repeated.

Referring to FIG. 17E, the second anodes AEb1, AEb2, and AEb3 may be formed in the areas corresponding to the first to third emissive areas PXA-B, PXA-G, and PXA-R.

The second-first anode AEb1 provided in the first emissive area PXA-B may be on the first insulating layer IL1. The second-first anode AEb1 may be connected with the first-first anode AEa1 through the first contact hole OP-C1. When viewed from above the plane (e.g., in a plan view), the second-first anode AEb1 may overlap the first-first anode AEa1.

The first sacrificial pattern SP1-P may be formed on the second-first anode AEb1. The first sacrificial pattern SP1-P may include IZO.

The second-second anode AEb2 provided in the second emissive area PXA-G may be on the first insulating layer IL1 and the second insulating layer IL2. The second-second anode AEb2 may be connected with the first-second anode AEa2 through the second contact hole OP-C2. When viewed from above the plane, the second-second anode AEb2 may overlap the first-second anode AEa2.

The second sacrificial pattern SP2-P may be formed on the second-second anode AEb2. The second sacrificial pattern SP2-P may include IZO.

The second-third anode AEb3 provided in the third emissive area PXA-R may be on the first insulating layer IL1, the second insulating layer IL2, and the third insulating layer IL3. The second-third anode AEb3 may be connected with the first-third anode AEa3 through the third contact hole OP-C3. When viewed from above the plane (e.g., in a plan view), the second-third anode AEb3 may overlap the first-third anode AEa3.

The third sacrificial pattern SP3-P may be formed on the second-third anode AEb3. The third sacrificial pattern SP3-P may include IZO.

As described above, the thicknesses of the insulating layers between the first anodes and the second anodes may be different for the plurality of pixels that emit light of different colors. Due to this, the light emission efficiency may be improved. Accordingly, the electronic device manufacturing method having improved display quality may be provided.

In embodiments, the plurality of insulating layers may be formed between the first anode and the second anode, and the plurality of insulating layers of the plurality of pixels may be spaced apart from one another. Due to this, the lifting phenomenon caused by the gas in the lower organic layer may be reduced. Accordingly, the electronic device manufacturing method having improved reliability may be provided.

While the subject matter of the present disclosure has been described with reference to embodiments thereof, it will be apparent to those of ordinary skill in the art that various suitable changes and modifications may be made thereto without departing from the spirit and scope of the present disclosure as set forth in the following claims, and equivalents thereof.

What is claimed is:

1. An electronic device manufacturing method comprising:
forming a base layer;
forming a circuit element layer on the base layer; and
forming a display element layer on the circuit element layer,
wherein the forming the display element layer comprises:
forming a first anode in each of a first emissive area, a second emissive area, and a third emissive area;
forming a first etching stopper layer on the first anode;
forming a first insulating layer on the first etching stopper layer;
forming a second etching stopper layer;
forming a second insulating layer;
etching the first insulating layer and the second insulating layer;
etching the first etching stopper layer and the second etching stopper layer; and
forming a second anode over the first anode.

2. The electronic device manufacturing method of claim 1, wherein the forming the display element layer further comprises forming a third insulating layer between the first anode and the first etching stopper layer, and
wherein the forming the third insulating layer is performed between the forming the first anode and the forming the first etching stopper layer.

3. The electronic device manufacturing method of claim 1, wherein the first anode comprises a reflective metal layer.

4. The electronic device manufacturing method of claim 1, wherein the second anode comprises a transparent electrode.

5. The electronic device manufacturing method of claim 1, wherein the forming the first etching stopper layer comprises forming the first etching stopper layer such that the first etching stopper layer overlaps the first emissive area when viewed from above a plane.

6. The electronic device manufacturing method of claim 5, wherein the forming the second etching stopper layer comprises forming the second etching stopper layer such that the second etching stopper layer overlaps the second emissive area when viewed from above the plane.

7. The electronic device manufacturing method of claim 1, wherein the etching the first insulating layer and the second insulating layer comprises exposing the circuit element layer in an area configured so as not to overlap the first emissive area, the second emissive area, and the third emissive area.

8. The electronic device manufacturing method of claim 1, wherein a first thickness between the first anode and the second anode in the first emissive area is less than a second thickness between the first anode and the second anode in the second emissive area.

9. The electronic device manufacturing method of claim 8, wherein the second thickness is less than a third thickness between the first anode and the second anode in the third emissive area.

10. The electronic device manufacturing method of claim 1, wherein the forming the second anode comprises thermally curing the second anode.

11. The electronic device manufacturing method of claim 10, wherein the forming the second anode further comprises removing outgas in the circuit element layer.

12. The electronic device manufacturing method of claim 1, wherein the first anode and the second anode overlap each other when viewed from above a plane.

13. The electronic device manufacturing method of claim 1, wherein the first anode makes contact with the second anode in the first emissive area.

14. The electronic device manufacturing method of claim 1, wherein the forming the display element layer further comprises forming a contact hole configured to overlap the first anode when viewed from above a plane, and
wherein the forming the contact hole is performed between the etching the first etching stopper layer and the second etching stopper layer and the forming the second anode.

15. The electronic device manufacturing method of claim 1, wherein a first contact hole configured to expose a portion of the first anode is defined in the first etching stopper layer, and
wherein a second contact hole configured to expose a portion of the first anode is defined in the second etching stopper layer.

16. The electronic device manufacturing method of claim 1, wherein the forming the display element layer further comprises forming photoresist on the second insulating layer configured to overlap the third emissive area, and
wherein the forming the photoresist is performed between the forming the second insulating layer and the etching the first insulating layer and the second insulating layer.

17. An electronic device manufacturing method comprising:
forming a base layer;
forming a circuit element layer on the base layer; and
forming a display element layer on the circuit element layer,
wherein the forming the display element layer includes:
forming a first anode in each of a first emissive area, a second emissive area, and a third emissive area;
forming a first insulating layer;
forming a second insulating layer on the first insulating layer;
forming a third insulating layer on the second insulating layer;
etching the first insulating layer, the second insulating layer, and the third insulating layer; and
forming a second anode on the first anode, and
wherein a first thickness between the first anode and the second anode in the first emissive area is less than a second thickness between the first anode and the second anode in the second emissive area, and the second thickness is less than a third thickness between the first anode and the second anode in the third emissive area.

18. The electronic device manufacturing method of claim 17, wherein the first anode comprises a reflective metal layer.

19. The electronic device manufacturing method of claim 17, wherein the second anode comprises a transparent electrode.

20. The electronic device manufacturing method of claim 17, wherein the first anode and the second anode overlap each other when viewed from above a plane.
